(19) United States
(12) Patent Application Publication
(10) Pub. No.: US 2024/0381639 A1
(43) Pub. Date: Nov. 14, 2024

(54) THREE-DIMENSIONAL MEMORY DEVICE WITH LAYER CONTACT VIA STRUCTURES LOCATED IN A MEMORY ARRAY REGION AND METHODS OF FORMING THE SAME

(71) Applicant: WESTERN DIGITAL TECHNOLOGIES, INC., SAN JOSE, CA (US)

(72) Inventors: Takaaki Iwai, Yokkaichi (JP); Yuji Totoki, Yokkaichi (JP); Keisuke Izumi, Yokkaichi (JP)

(21) Appl. No.: 18/233,759

(22) Filed: Aug. 14, 2023

Related U.S. Application Data
(60) Provisional application No. 63/501,182, filed on May 10, 2023.

(51) Int. Cl. H10B 43/27; H01L 23/00; H01L 25/00; H01L 25/065; H01L 25/18; H10B 41/27; H10B 41/35; H10B 43/35; H10B 80/00

(52) U.S. Cl. CPC H10B 43/27; H01L 24/08; H01L 24/80; H01L 25/0657; H01L 25/18; H01L 25/50; H10B 41/27; H10B 41/35; H10B 43/35; H10B 80/00; H01L 2224/08145; H01L 2224/80895; H01L 2224/80896; H01L 2924/1431; H01L 2924/14511

(57) ABSTRACT

A three-dimensional memory device includes an alternating stack of insulating layers and electrically conductive layers, an array of memory openings vertically extending through the alternating stack, memory-opening-free areas located in the array of the memory openings in a plan view, an array of memory opening fill structures located in the array of memory openings, and layer contact assemblies located within the memory-opening-free areas in the plan view. Each of the memory opening fill structures includes a respective vertical semiconductor channel and respective memory elements located at levels of the electrically conductive layers. Each of the layer contact assemblies includes a respective layer contact via structure contacting a respective one of the electrically conductive layers, and a respective insulating spacer that laterally surrounds the respective layer contact via structure.

### FIELD

The present disclosure relates generally to the field of semiconductor devices, and particularly to a three-dimensional memory device including layer contact via structures located in a memory array region and methods of forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device includes an alternating stack of insulating layers and electrically conductive layers, an array of memory openings vertically extending through the alternating stack, memory-opening-free areas located in the array of the memory openings in a plan view, an array of memory opening fill structures located in the array of memory openings, and layer contact assemblies located within the memory-opening-free areas in the plan view. Each of the memory opening fill structures includes a respective vertical semiconductor channel and respective memory elements located at levels of the electrically conductive layers. Each of the layer contact assemblies includes a respective layer contact via structure contacting a respective one of the electrically conductive layers, and a respective insulating spacer that laterally surrounds the respective layer contact via structure.

According to another aspect of the present disclosure, a method of forming a three-dimensional memory device is provided. The method comprises: forming an alternating stack of insulating layers and sacrificial material layers over a substrate; forming an array of memory openings through the alternating stack, wherein the array of memory openings is arranged to provide memory-opening-free areas therein in a plan view; forming an array of memory opening fill structures in the array of memory openings, wherein each of the memory opening fill structures comprises a respective vertical semiconductor channel and respective memory elements located at levels of the electrically conductive layers; forming in-process via structures including sacrificial via fill material portions within areas of the memory-opening-free areas in the plan view, wherein each of the in-process via structures vertically extends through a respective subset of layers within the alternating stack; replacing the sacrificial material layers with electrically conductive layers; and replacing the sacrificial via fill material portions with layer contact via structures to form layer contact assemblies, wherein each of the layer contact assemblies comprises a respective layer contact via structure contacting a respective one of the electrically conductive layers and further comprises a respective insulating spacer that laterally surrounds the respective layer contact via structure.

### BRIEF DESCRIPTION OF THE DRAWINGS

FIG. 1 is a vertical cross-sectional view of an exemplary structure after formation of an alternating stack of insulating layers and sacrificial material layers according to an embodiment of the present disclosure.

FIG. 2A is a vertical cross-sectional view of the exemplary structure after formation of memory openings and support openings according to an embodiment of the present disclosure.

FIG. 2B is a top-down view of the exemplary structure of FIG. 2A. The vertical plane A-A′ is the vertical cross-sectional plane of FIG. 2A.

FIG. 3 is a vertical cross-sectional view of the exemplary structure after formation of sacrificial memory opening fill structures according to an embodiment of the present disclosure.

FIG. 4 is a vertical cross-sectional view of the exemplary structure after formation of support pillar structures according to an embodiment of the present disclosure.

FIG. 5 is a vertical cross-sectional view of the exemplary structure after removal of the sacrificial memory opening fill structures according to an embodiment of the present disclosure.

FIGS. 6A-6H is a vertical cross-sectional view of a memory opening during formation of a memory opening fill structure.

FIG. 7A is a vertical cross-sectional view of the exemplary structure after formation of memory opening fill structures according to an embodiment of the present disclosure.

FIG. 7B is a top-down view of the exemplary structure of FIG. 7A. The vertical plane A-A′ is the vertical cross-sectional plane of FIG. 7A.

FIG. 7C is a top-down view of a first alternative configuration of the exemplary structure after the processing steps of FIGS. 7A and 7B according to an alternative embodiment of the present disclosure.

FIG. 7D is a top-down view of a second alternative configuration of the exemplary structure after the processing steps of FIGS. 7A and 7B according to another alternative embodiment of the present disclosure.

FIG. 8A is a vertical cross-sectional view of the exemplary structure after formation of a patterned hard mask layer and contact via cavities according to an embodiment of the present disclosure.

FIG. 8B is a top-down view of the exemplary structure of FIG. 8A. The vertical plane A-A′ is a plane of the vertical cross-sectional view of FIG. 8A.

FIG. 8C is a vertical cross-sectional view of the exemplary structure along the vertical plane C-C′ of FIG. 8B.

FIG. 9A is a vertical cross-sectional view of the exemplary structure after formation of an insulating liner layer, sacrificial via fill material portions, a sacrificial capping layer, and isolation trenches according to an embodiment of the present disclosure.

FIG. 9B is a top-down view of the exemplary structure of FIG. 9A. The vertical plane A-A′ is a plane of the vertical cross-sectional view of FIG. 9A.

FIG. 9C is a vertical cross-sectional view of the exemplary structure along the vertical plane C-C′ of FIG. 9B.

FIG. 10A is a vertical cross-sectional view of the exemplary structure after formation of lateral recesses according to an embodiment of the present disclosure.

FIG. 10B is a top-down view of the exemplary structure of FIG. 10A. The vertical plane A-A′ is a plane of the vertical cross-sectional view of FIG. 10A.

FIG. 10C is a vertical cross-sectional view of the exemplary structure along the vertical plane C-C′ of FIG. 10B.

FIG. 11A is a vertical cross-sectional view of the exemplary structure after formation of electrically conductive layers according to an embodiment of the present disclosure.

FIG. 11B is a top-down view of the exemplary structure of FIG. 11A. The vertical plane A-A′ is a plane of the vertical cross-sectional view of FIG. 11A.

FIG. 11C is a vertical cross-sectional view of the exemplary structure along the vertical plane C-C′ of FIG. 11B.

FIG. 11D is a vertical cross-sectional view of a region around a memory opening fill structures in the exemplary structure after the processing steps of FIGS. 11A-11C.

FIG. 12A is a vertical cross-sectional view of the exemplary structure after formation of isolation trench fill structures and removal of the sacrificial capping layer according to an embodiment of the present disclosure.

FIG. 12B is a top-down view of the exemplary structure of FIG. 12A. The vertical plane A-A′ is a plane of the vertical cross-sectional view of FIG. 12A.

FIG. 12C is a vertical cross-sectional view of the exemplary structure along the vertical plane C-C′ of FIG. 12B.

FIG. 13A is a vertical cross-sectional view of the exemplary structure after removal of the sacrificial via fill material portions and formation of insulating spacers according to an embodiment of the present disclosure.

FIG. 13B is a top-down view of the exemplary structure of FIG. 13A. The vertical plane A-A′ is a plane of the vertical cross-sectional view of FIG. 13A.

FIG. 14A is a vertical cross-sectional view of the exemplary structure after formation of layer contact via structures and drain-select-level dielectric isolation structures according to an embodiment of the present disclosure.

FIG. 14B is a top-down view of the exemplary structure of FIG. 14A. The vertical plane A-A′ is a plane of the vertical cross-sectional view of FIG. 14A.

FIG. 14C is a vertical cross-sectional view of the exemplary structure along the vertical plane C-C′ of FIG. 14B.

FIG. 14D is a top-down view of the first alternative configuration of the exemplary structure after the processing steps of FIGS. 14A-14C according to an alternative embodiment of the present disclosure.

FIG. 14E is a top-down view of the second alternative configuration of the exemplary structure after the processing steps of FIGS. 14A-14C according to another alternative embodiment of the present disclosure.

FIG. 15A is a vertical cross-sectional view of the exemplary structure after formation a contact-level dielectric layer, drain contact via structures, and contact-level extension via structures according to an embodiment of the present disclosure.

FIG. 15B is a top-down view of the exemplary structure of FIG. 15A. The vertical plane A-A′ is a plane of the vertical cross-sectional view of FIG. 15A.

FIG. 15C is a vertical cross-sectional view of the exemplary structure along the vertical plane C-C′ of FIG. 15B.

FIG. 16A is a vertical cross-sectional view of the exemplary structure after formation a connection-level dielectric layer, drain connection via structures, connection-level extension via structures, a line-level dielectric layer, bit lines, and layer-connection metal lines according to an embodiment of the present disclosure.

FIG. 16B is a top-down view of the exemplary structure of FIG. 16A. The vertical plane A-A′ is a plane of the vertical cross-sectional view of FIG. 16A.

FIG. 16C is a vertical cross-sectional view of the exemplary structure along the vertical plane C-C′ of FIG. 16B.

FIG. 16D is a vertical cross-sectional view of the exemplary structure along the vertical plane D-D′ of FIG. 16B.

FIG. 17 is a vertical cross-sectional view of the exemplary structure after formation of upper dielectric material layers and upper metal interconnect structures according to an embodiment of the present disclosure.

FIG. 18 is a vertical cross-sectional view of the exemplary structure after attaching a logic die to a memory die according to an embodiment of the present disclosure.

FIG. 19A is a magnified vertical cross-sectional view of a region between a bonding interface between the logic die and memory die in the exemplary structure of FIG. 18.

FIG. 19B is a horizontal cross-sectional view along the horizontal plane B-B′ of FIG. 19A.

FIG. 19C is a horizontal cross-sectional view along the horizontal plane C-C′ of FIG. 19A.

FIG. 20A is an alternative horizontal cross-sectional view of memory-side bonding pads according to an embodiment of the present disclosure.

FIG. 20B is an alternative horizontal cross-sectional view of logic-side bonding pads according to an embodiment of the present disclosure.

### DETAILED DESCRIPTION

As discussed above, the embodiments of the present disclosure are directed to a three-dimensional memory device including layer contact via structures located in a memory array region and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many a number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

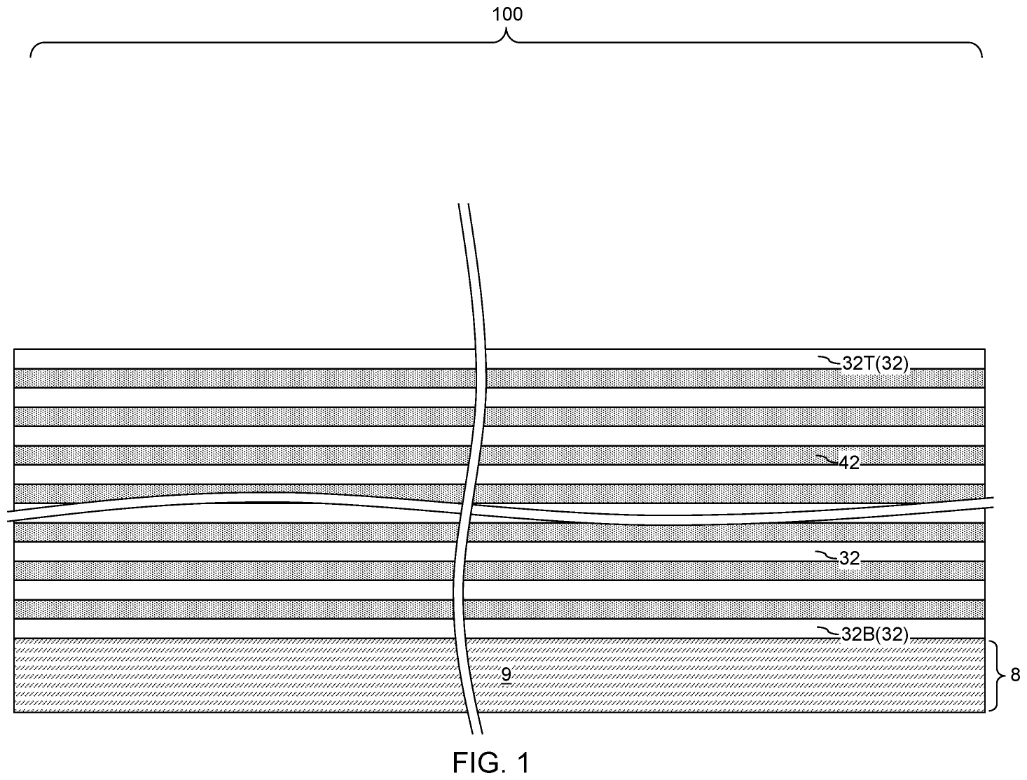

Referring to FIG. 1, an exemplary structure according to an embodiment of the present disclosure includes a substrate 8. The substrate 8 may be a carrier substrate that is subsequently removed. The substrate 8 may comprise a semiconductor material (e.g., a silicon wafer), an insulating material, a conductive material, or a combination thereof. The substrate 8 comprises a material that can provide structural support to material portions that are subsequently formed thereupon. The substrate 8 comprises a substrate material layer 9 at least at an upper portion thereof. In one embodiment, the substrate material layer 9 may be a semiconductor material layer, such as a silicon layer or a doped well in a silicon wafer. In another embodiment, the substrate material layer 9 may be an insulating layer, such as silicon oxide. Optionally, lower metal interconnect structures 480 may be located below the insulating substrate material layer 9 or may be embedded in the insulating substrate material layer 9. The exemplary structure comprises a memory array region 100 in which a three-dimensional memory array is subsequently formed.

An alternating stack of insulating layers 32 and sacrificial material layers 42 can be formed over the substrate 8. The alternating stack of insulating layers 32 and sacrificial material layers 42 is a vertically alternating sequence of the insulating layers 32 and the sacrificial material layers 42 that alternate along the vertical direction. Each insulating layer 32 can include an insulating material, and each sacrificial material layer 42 can include a sacrificial material. As used herein, a “sacrificial material” refers to a material that is removed during a subsequent processing step.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness thereamongst, or may have different thicknesses. The second elements may have the same thickness thereamongst, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

Insulating materials that can be employed for the insulating layers 32 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The sacrificial material of the sacrificial material layers 42 comprises a material can be removed selective to the material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise a dielectric material, a semiconductor material, or a conductive material. The material of the sacrificial material layers 42 can be subsequently replaced with electrically conductive electrodes which can function, for example, as control gate electrodes of a vertical NAND device. In one embodiment, the sacrificial material layers 42 can be material layers that comprise silicon nitride.

In one embodiment, the insulating layers 32 can include silicon oxide, and sacrificial material layers can include silicon nitride sacrificial material layers. The insulating layers 32 can be deposited, for example, by chemical vapor deposition (CVD). For example, if silicon oxide is employed for the insulating layers 32, tetraethylorthosilicate (TEOS) can be employed as the precursor material for the CVD process. The second material of the sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be employed for each insulating layer 32 and for each sacrificial material layer 42. The number of repetitions of the pairs of a insulating layer 32 and a sacrificial material layer 42 can be in a range from 2 to 1,024, and typically from 8 to 256, although a greater number of repetitions can also be employed. In one embodiment, each sacrificial material layer 42 in the vertically alternating sequence (32, 42) can have a uniform thickness that is substantially invariant within each respective sacrificial material layer 42. The bottommost layer among the insulating layers 32 is herein referred to as a bottommost insulating layer 32B. The topmost layer among the insulating layers 32 is herein referred to as a topmost insulating layer 32T.

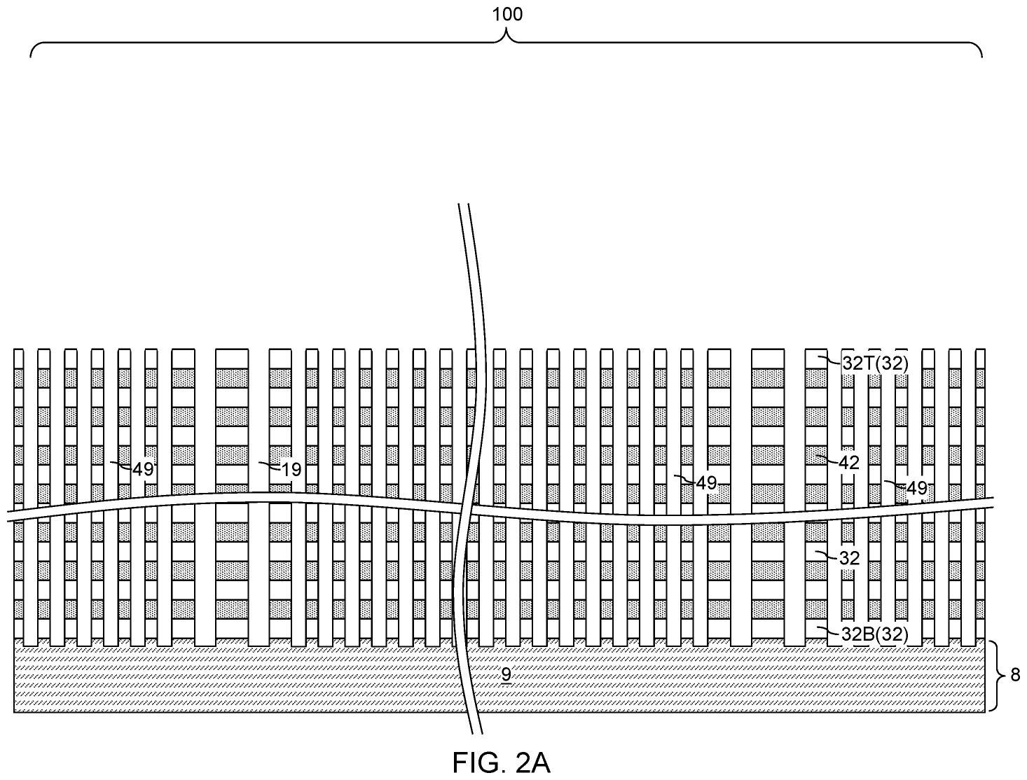

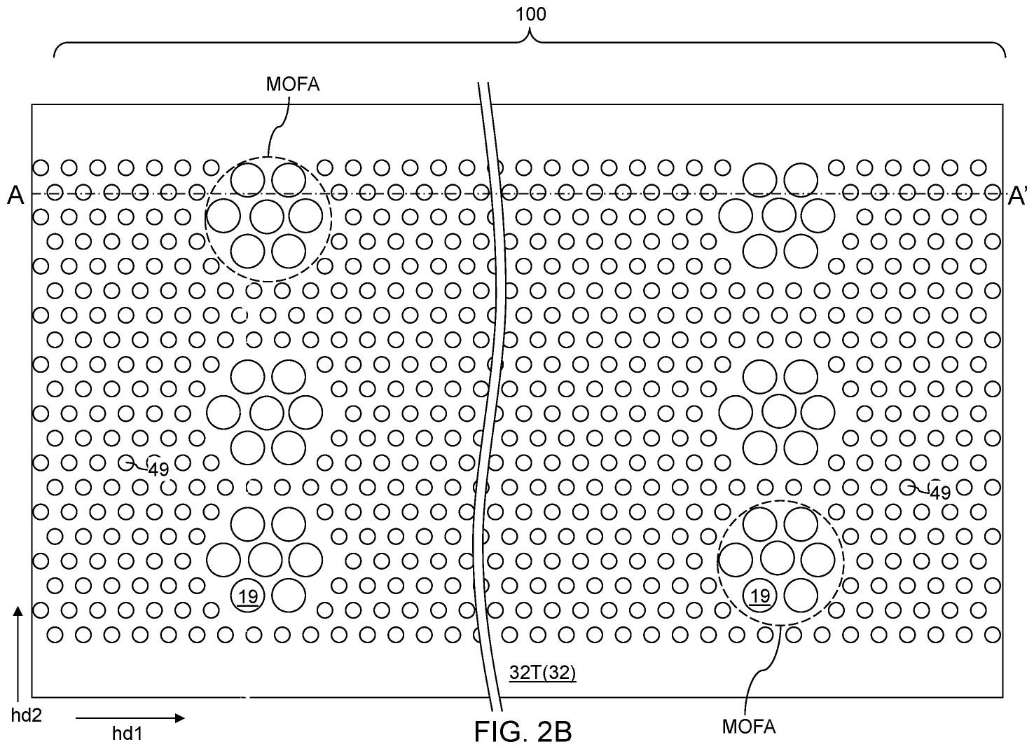

Referring to FIGS. 2A and 2B, a lithographic material stack (not shown) including at least a photoresist layer can be formed over the topmost insulating layer 32T, and can be lithographically patterned to form openings therein. As shown in FIG. 2B, the pattern in the lithographic material stack comprises memory-opening-free areas MOFA that are free of openings therein. The pattern in the lithographic material stack can be transferred through the alternating stack (32, 42) by at least one anisotropic etch that employs the patterned lithographic material stack as an etch mask. Portions of the alternating stack (32, 42) underlying the openings in the patterned lithographic material stack are etched to form memory openings 49 and support openings 19. As used herein, a “memory opening” refers to a structure in which memory elements, such as a memory stack structure, is subsequently formed. As used herein, a “support opening” refers to a structure in which a support structure (such as a support pillar structure) that mechanically supports other elements is subsequently formed. In one embodiment, the diameter of the support openings 19 may be larger than the diameter of the memory openings 49. In one embodiment, the support openings 19 are arranged in a hexagonal close packed layout (e.g., with peripheral support openings 19 located at vertices of an imaginary hexagon around a middle support opening at the center of the hexagon) in each memory-opening-free area MOFA. In other embodiments, the support openings 19 may have a different layout. In one embodiment, each memory-opening-free area MOFA can be laterally surrounded by a set of support openings 19. In one embodiment, the memory-opening-free areas MOFA lack any memory openings 49 therein and may be arranged as a two-dimensional array. In one embodiment, the array may include multiple rows of memory-opening-free areas MOFA. In one embodiment, each row of memory-opening-free areas MOFA may include a plurality of memory-opening-free areas MOFA that are arranged along a first horizontal direction (e.g., word line direction) hd1. However, in other embodiments, the memory-opening-free areas MOFA are not arranged in rows.

The chemistry of the anisotropic etch process employed to etch through the materials of the alternating stack (32, 42) can alternate to optimize etching of the first and second materials in the alternating stack (32, 42). The anisotropic etch can be, for example, a series of reactive ion etches. The sidewalls of the memory openings 49 and the support openings 19 can be substantially vertical, or can be tapered. The patterned lithographic material stack can be subsequently removed, for example, by ashing.

The memory openings 49 and the support openings 19 can extend from the top surface of the alternating stack (32, 42) to at least the horizontal plane including the topmost surface of the substrate material layer 9. In one embodiment, an overetch into the substrate material layer 9 may be optionally performed after the top surface of the substrate material layer 9 is physically exposed at a bottom of each memory opening 49 and each support opening 19. The overetch may be performed prior to, or after, removal of the lithographic material stack. In other words, the recessed surfaces of the substrate material layer 9 may be vertically offset from the un-recessed top surfaces of the substrate material layer 9 by a recess depth. The recess depth can be, for example, in a range from 1 nm to 50 nm, although lesser and greater recess depths can also be employed. The overetch is optional, and may be omitted. If the overetch is not performed, the bottom surfaces of the memory openings 49 and the support openings 19 can be coplanar with the topmost surface of the substrate material layer 9. Each of the memory openings 49 and the support openings 19 may include a sidewall (or a plurality of sidewalls) that extends substantially perpendicular to the topmost surface of the substrate.

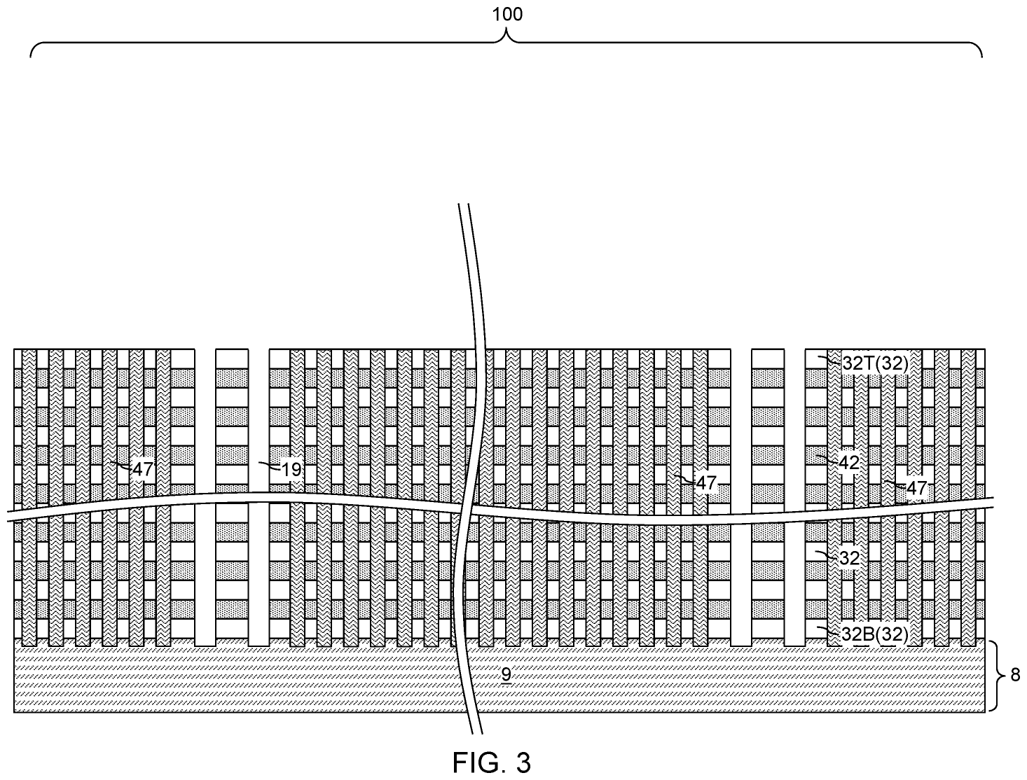

Referring to FIG. 3, in one embodiment, a sacrificial fill material can be deposited in the memory openings 49 and the support openings 19. The sacrificial fill material may be any material that may be removed selective to the materials of the insulating layers 32, the sacrificial material layers 42, and the substrate material layer 9. For example, the sacrificial fill material may comprise a carbon-based material such as amorphous carbon or diamond-like carbon, a semiconductor material such as a silicon-germanium alloy, polysilicon or amorphous silicon, or a dielectric material such as borosilicate glass or organosilicate glass. Optionally, a thin etch stop liner (not shown) may be employed to facilitate subsequent selective removal of the sacrificial fill material. Excess portions of the sacrificial fill material may be removed from above the horizontal plane including the top surface of the topmost insulating layer 32T. Each remaining portion of the sacrificial fill material filling a memory opening 49 constitutes a sacrificial memory opening fill structure 47. Each remaining portion of the sacrificial fill material filling a support opening 19 constitutes a sacrificial support opening fill structure (not shown).

A photoresist layer (not shown) can be applied over the exemplary structure, and can be lithographically patterned to cover the sacrificial memory opening fill structures 47 while not covering the sacrificial support opening fill structures. The sacrificial support opening fill structures can be removed by removing the sacrificial fill material within the areas that are not covered by the photoresist layer. The sacrificial fill material may be removed, for example, by ashing or by performing an etch process such as a wet etch process. Cavities are formed in the support openings 19. The photoresist layer can be removed, for example, by ashing.

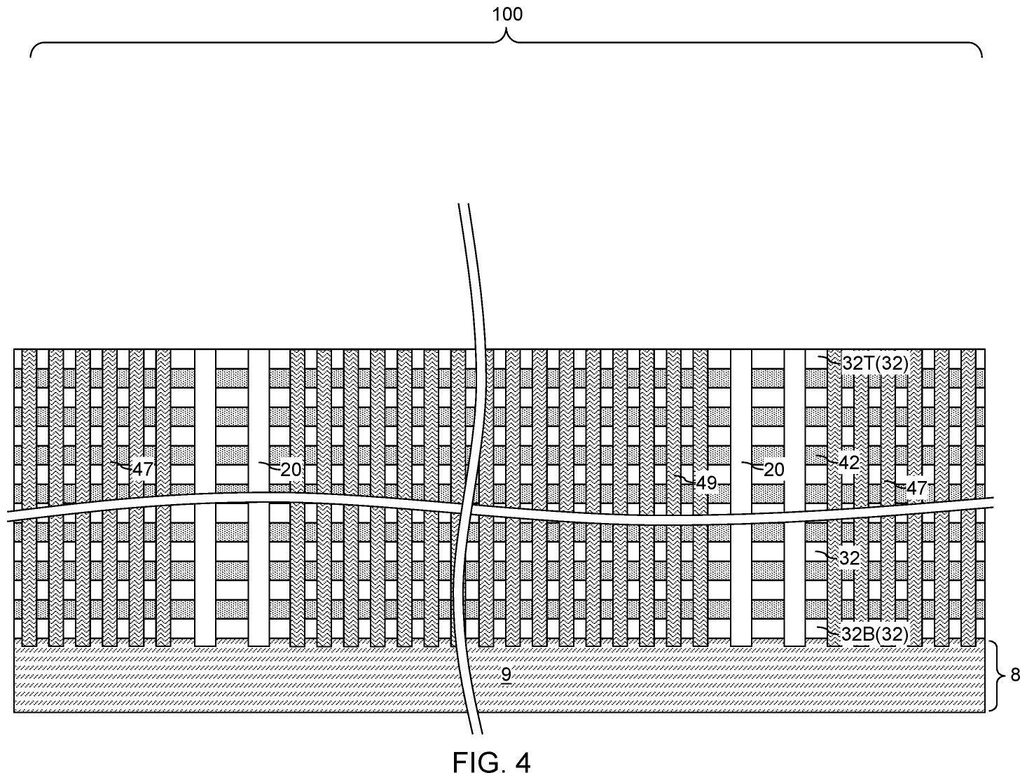

Referring to FIG. 4, a dielectric fill material such as undoped silicate glass (i.e., silicon oxide) or a doped silicate glass can be deposited in the support openings 19 employing a conformal deposition process such as a chemical vapor deposition process. Portions of the dielectric fill material that overlie the topmost insulating layer 32T may be removed, for example, by chemical mechanical polishing or by an etch back process, such as a wet etch process employing dilute hydrofluoric acid. Remaining portions of the dielectric fill material that fill the support openings 19 comprise support pillar structures 20, which are dielectric pillar structures that provide structural support to the exemplary structure during a subsequent processing step in which the sacrificial material layers 42 are removed. In one embodiment, each of the memory-opening-free areas MOFA can be laterally surrounded by a respective set of support pillar structures 20.

Thus, in one embodiment, clusters of support pillar structures 20 vertically extending through the alternating stack (32, 42) can be formed. Each of the support pillar structures 20 comprises a dielectric fill material, such as silicon oxide, and each cluster of support pillar structures 20 within the clusters of support pillar structures 20 laterally surrounds a respective one of the memory-opening-free areas MOFA. The clusters of support pillar structures 20 may be arranged in a hexagonal close packed layout or in a different layout in each of the memory-opening-free areas MOFA

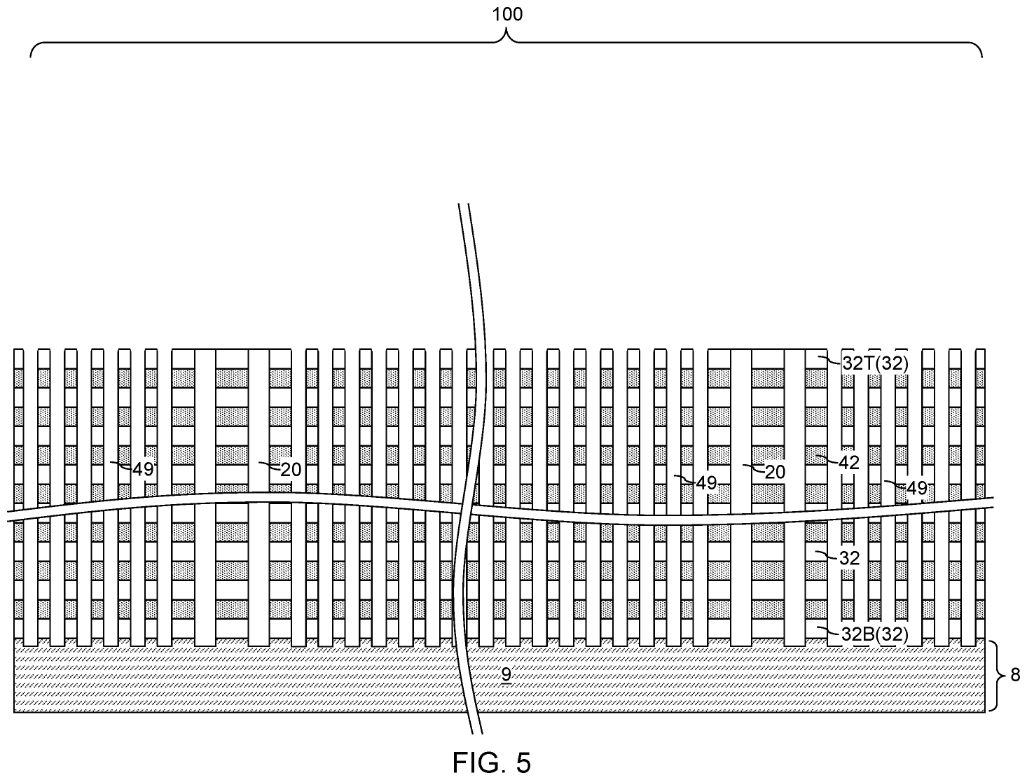

Referring to FIG. 5, the sacrificial fill material of the sacrificial memory opening fill structures 47 can be removed selective to the materials of the insulating layers 32, the sacrificial material layers 42, the semiconductor material layer 10, and the support pillar structures 20. The sacrificial memory opening fill structures 47 may be removed by ashing or by performing an etch process such as a wet etch process. Cavities are formed in volumes of the memory openings 49 from the which the sacrificial memory opening fill structures 47 are removed.

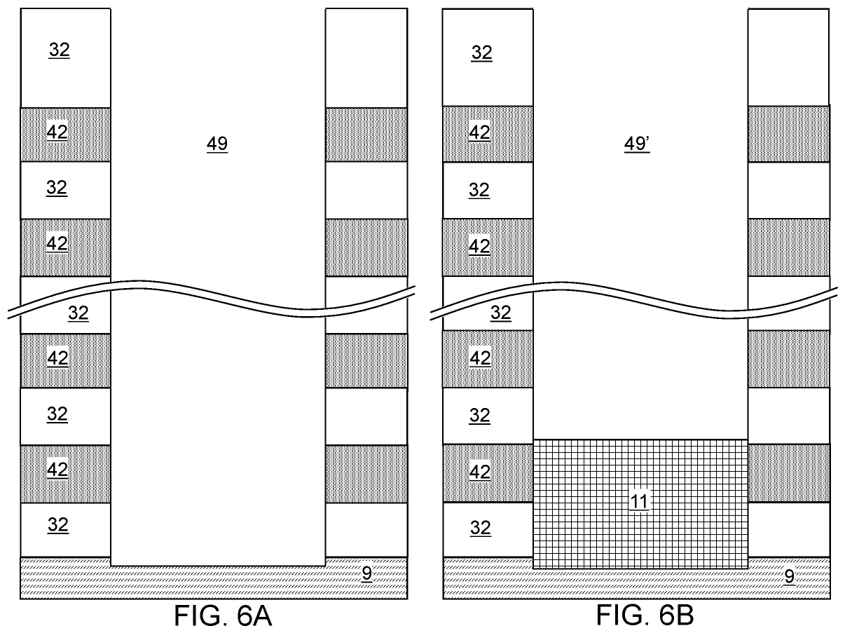

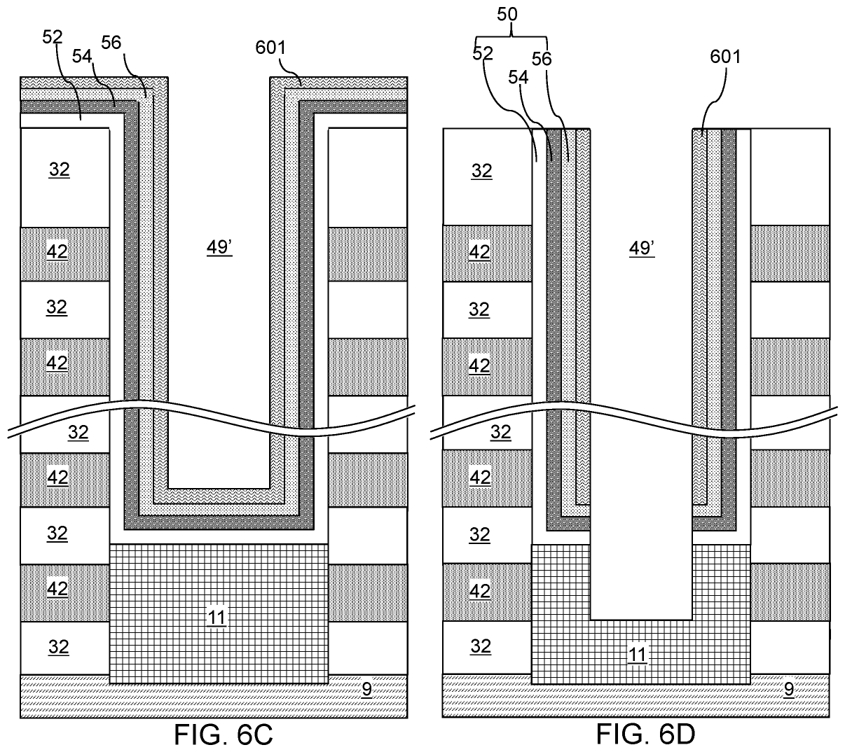

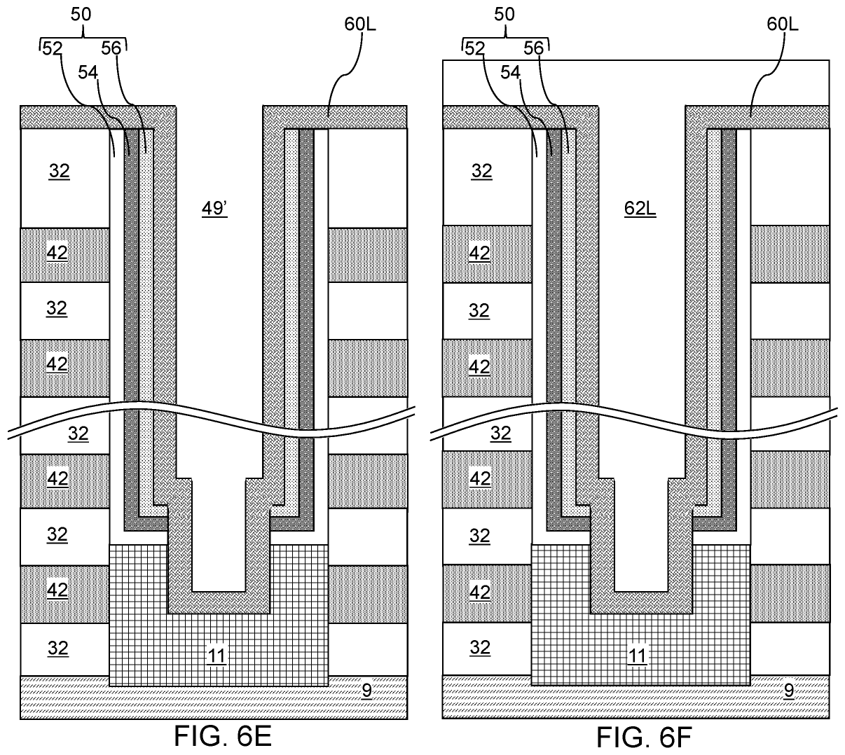

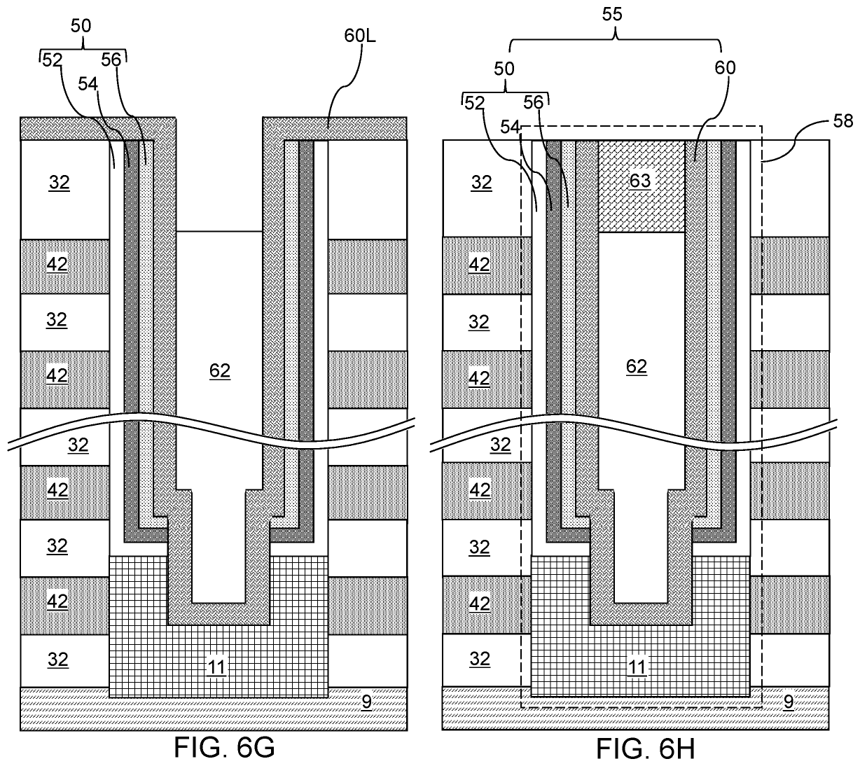

FIGS. 6A-6H is a vertical cross-sectional view of a memory opening during formation of a memory opening fill structure 58. The same structural change occurs simultaneously in each of the other memory openings 49. In an alternative embodiment, the steps described above with respect to FIGS. 3, 4 and 5 may be omitted. In this alternative embodiment, the memory openings 49 and the support openings 19 are filled with the same set of layers during the same processing steps. Thus, memory opening fill structures 58 are formed in the memory openings 49 at the same time as support structures 20 are formed in the support openings 19. In the alternative embodiment, the memory opening fill structures 58 have the same layers and materials as the support structures 20.

Referring to FIG. 6A, a memory opening 49 in the exemplary device structure of FIG. 5 is illustrated. The memory opening 49 extends through the alternating stack (32, 42), and optionally into an upper portion of the substrate material layer 9. The recess depth of the bottom surface of each memory opening with respect to the top surface of the substrate material layer 9 can be in a range from 0 nm to 30 nm, although greater recess depths can also be employed. Optionally, the sacrificial material layers 42 can be laterally recessed partially to form lateral recesses (not shown), for example, by an isotropic etch.

Referring to FIG. 6B, an optional pedestal channel portion (e.g., an epitaxial pedestal) 11 can be formed at the bottom portion of each memory opening 49 and each support openings 19, for example, by selective epitaxy. Each pedestal channel portion 11 comprises a single crystalline semiconductor material (e.g., single crystal silicon) in epitaxial alignment with the single crystalline substrate material layer 9. In one embodiment, the pedestal channel portion 11 can be doped with electrical dopants of the same conductivity type as the substrate material layer 9. In one embodiment, the top surface of each pedestal channel portion 11 can be formed above a horizontal plane including the top surface of at least one bottommost sacrificial material layer 42. In this case, at least one source select gate electrode can be subsequently formed by replacing each sacrificial material layer 42 located below the horizontal plane including the top surfaces of the pedestal channel portions 11 with a respective conductive material layer. The pedestal channel portion 11 can be a portion of a transistor channel that extends between a source region to be subsequently formed in or above the substrate material layer 9 and a drain region to be subsequently formed in an upper portion of the memory opening 49. A memory cavity 49′ is present in the unfilled portion of the memory opening 49 above the pedestal channel portion 11. In one embodiment, the pedestal channel portion 11 can comprise single crystalline silicon. In one embodiment, the pedestal channel portion 11 can have a doping of the first conductivity type, which is the same as the conductivity type of the substrate material layer 9 that the pedestal channel portion contacts.

Referring to FIG. 6C, a stack of layers including an optional blocking dielectric layer 52, a memory material layer 54, a dielectric material liner 56, and an optional sacrificial cover material layer 601 can be sequentially deposited in the memory openings 49 by a respective conformal deposition process.

The blocking dielectric layer 52 can include a single dielectric material layer or a stack of a plurality of dielectric material layers. In one embodiment, the blocking dielectric layer can include a dielectric metal oxide layer consisting essentially of a dielectric metal oxide. In one embodiment, the blocking dielectric layer 52 includes aluminum oxide. In one embodiment, the blocking dielectric layer 52 can include multiple dielectric metal oxide layers having different material compositions. Alternatively or additionally, the blocking dielectric layer 52 can include a dielectric semiconductor compound such as silicon oxide, silicon oxynitride, silicon nitride, or a combination thereof. In one embodiment, the blocking dielectric layer 52 can include silicon oxide. The thickness of the blocking dielectric layer 52 can be in a range from 3 nm to 20 nm, although lesser and greater thicknesses can also be employed. Alternatively, the blocking dielectric layer 52 can be omitted, and a backside blocking dielectric layer can be formed after formation of backside recesses on surfaces of memory films to be subsequently formed.

Subsequently, the memory material layer 54 can be formed. Generally, the memory material layer 54 may comprise any memory material that can store a data bit. The data bit may be stored in the form of electrical charges trapped therein, in the form of a resistive state of a material due to changes in the material phase, resistivity or ferroelectric property. In one embodiment, the memory material layer 54 may comprise a charge storage layer. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer.

In another embodiment, the sacrificial material layers 42 can be laterally recessed with respect to the sidewalls of the insulating layers 32, and a combination of a deposition process and an anisotropic etch process can be employed to form the memory material layer 54 as a plurality of memory material portions that are vertically spaced apart. While the memory material layer 54 is illustrated as a single continuous layer, embodiments are expressly contemplated herein in which the memory material layer 54 is replaced with a plurality of discrete memory material portions (which can be charge trapping material portions or electrically isolated conductive material portions) that are vertically spaced apart. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

The dielectric material liner 56 includes a dielectric material. In one embodiment, the dielectric material liner 56 may comprise a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The tunneling dielectric layer can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the tunneling dielectric layer can include a stack of a first silicon oxide layer, a silicon oxynitride layer, and a second silicon oxide layer, which is commonly known as an ONO stack. In one embodiment, the tunneling dielectric layer can include a silicon oxide layer that is substantially free of carbon or a silicon oxynitride layer that is substantially free of carbon. The thickness of the tunneling dielectric layer can be in a range from 2 nm to 20 nm, although lesser and greater thicknesses can also be employed. Alternatively, a different type of dielectric material layer may be employed as the dielectric material liner 56.

The optional sacrificial cover material layer 601 includes a sacrificial material that can be subsequently removed selective to the material of the dielectric material liner 56. In one embodiment, the sacrificial cover material layer 601 can include a semiconductor material such as amorphous silicon, or may include a carbon-based material such as amorphous carbon or diamond-like carbon (DLC). The sacrificial cover material layer 601 can be formed by a conformal deposition method such as low pressure chemical vapor deposition (LPCVD). The thickness of the sacrificial cover material layer 601 can be in a range from 2 nm to 10 nm, although lesser and greater thicknesses can also be employed. A memory cavity 49′ is formed in the volume of each memory opening 49 that is not filled with the deposited material layers (52, 54, 56, 601).

Referring to FIG. 6D, the optional sacrificial cover material layer 601, the dielectric material liner 56, the memory material layer 54, and the blocking dielectric layer 52 overlying the topmost insulating layer 32T are sequentially anisotropically etched employing at least one anisotropic etch process. The portions of the sacrificial cover material layer 601, the dielectric material liner 56, the memory material layer 54, and the blocking dielectric layer 52 located above the top surface of the topmost insulating layer 32T can be removed by the at least one anisotropic etch process. Further, the horizontal portions of the sacrificial cover material layer 601, the dielectric material liner 56, the memory material layer 54, and the blocking dielectric layer 52 at a bottom of each memory cavity 49′ can be removed to form openings in remaining portions thereof. Each of the sacrificial cover material layer 601, the dielectric material liner 56, the memory material layer 54, and the blocking dielectric layer 52 can be etched by a respective anisotropic etch process employing a respective etch chemistry, which may, or may not, be the same for the various material layers.

Each remaining portion of the sacrificial cover material layer 601 can have a tubular configuration. The memory material layer 54 can comprise a charge trapping material, a floating gate material, a ferroelectric material, a resistive memory material that can provide at least two different levels of resistivity (such as a phase change material), or any other memory material that can store information by a change in state. In one embodiment, each memory material layer 54 can include a vertical stack of charge storage regions that store electrical charges upon programming. In one embodiment, the memory material layer 54 can be a memory material layer in which each portion adjacent to the sacrificial material layers 42 constitutes a charge storage region.

A surface of the pedestal channel portion 11 (or a surface of the substrate material layer 9 in case the pedestal channel portions 11 are not employed) can be physically exposed underneath the opening through the sacrificial cover material layer 601, the dielectric material liner 56, the memory material layer 54, and the blocking dielectric layer 52. Optionally, the physically exposed semiconductor surface at the bottom of each memory cavity 49′ can be vertically recessed so that the recessed semiconductor surface underneath the memory cavity 49′ is vertically offset from the topmost surface of the pedestal channel portion 11 (or of the substrate material layer 9 in case pedestal channel portions 11 are not employed) by a recess distance. A dielectric material liner 56 is located over the memory material layer 54. A set of a blocking dielectric layer 52, a memory material layer 54, and a dielectric material liner 56 in a memory opening 49 constitutes a memory film 50, which includes a plurality of charge storage regions (comprising portions of the memory material layer 54) that are insulated from surrounding materials by the blocking dielectric layer 52 and the dielectric material liner 56. In one embodiment, the sacrificial cover material layer 601, the dielectric material liner 56, the memory material layer 54, and the blocking dielectric layer 52 can have vertically coincident sidewalls. Optionally, the sacrificial cover material layer 601 can be subsequently removed selective to the material of the dielectric material liner 56. If the sacrificial cover material layer 601 includes amorphous silicon, then a wet etch process employing hot trimethyl-2 hydroxyethyl ammonium hydroxide (“hot TMY”) or tetramethyl ammonium hydroxide (TMAH) can be performed to remove the sacrificial cover material layer 601.

Referring to FIG. 6E, a semiconductor channel layer 60L can be deposited directly on the semiconductor surface of the pedestal channel portion 11 or the substrate material layer 9 if the pedestal channel portion 11 is omitted, and directly on the dielectric material liner 56 (or on the silicon sacrificial cover material layer 601 if still present). The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art.

In one embodiment, the semiconductor channel layer 60L includes amorphous silicon or polysilicon. The semiconductor channel layer 60L can have a doping of a first conductivity type, which is the same as the conductivity type of the substrate material layer 9 and the pedestal channel portions 11. The semiconductor channel layer 60L can be formed by a conformal deposition method such as low pressure chemical vapor deposition (LPCVD). The thickness of the semiconductor channel layer 60L can be in a range from 2 nm to 10 nm, although lesser and greater thicknesses can also be employed. The semiconductor channel layer 60L may partially fill the memory cavity 49′ in each memory opening, or may fully fill the cavity in each memory opening.

Referring to FIG. 6F, in case the memory cavity 49′ in each memory opening is not completely filled by the semiconductor channel layer 60L, a dielectric core layer 62L can be deposited in the memory cavity 49′ to fill any remaining portion of the memory cavity 49′ within each memory opening. The dielectric core layer 62L includes a dielectric material such as silicon oxide or organosilicate glass. The dielectric core layer 62L can be deposited by a conformal deposition method such as low pressure chemical vapor deposition (LPCVD), or by a self-planarizing deposition process such as spin coating.

Referring to FIG. 6G, the horizontal portion of the dielectric core layer 62L can be removed, for example, by a recess etch process such that each remaining portions of the dielectric core layer 62L is located within a respective memory opening 49 and has a respective top surface below the horizontal plane including the top surface of the topmost insulating layer 32T. Each remaining portion of the dielectric core layer 62L constitutes a dielectric core 62.

Referring to FIG. 6H, a doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60. The vertical semiconductor channel 60 is formed directly on the dielectric material liner 56.

Each adjoining set of a blocking dielectric layer 52, a memory material layer 54, and a dielectric material liner 56 collectively constitute a memory film 50, which can store electrical charges or electrical polarization with a macroscopic retention time. As used herein, a macroscopic retention time refers to a retention time suitable for operation of a memory device as a permanent memory device such as a retention time in excess of 24 hours. In some embodiments, a blocking dielectric layer 52 may not be present in the memory film 50 at this step, and a backside blocking dielectric layer may be subsequently formed after formation of backside recesses.

Each combination of a memory film 50 and a vertical semiconductor channel 60 within a memory opening 49 constitutes a memory stack structure 55. The memory stack structure 55 is a combination of a semiconductor channel, a dielectric material liner, a plurality of memory elements as embodied as portions of the memory material layer 54, and an optional blocking dielectric layer 52. An entire set of material portions that fills a memory opening 49 is herein referred to as a memory opening fill structure 58. An entire set of material portions that fills a support opening 19 constitutes a support pillar structure.

Generally, a memory opening fill structure 58 can be formed in each memory opening 49. The memory opening fill structure 58 comprises an optional blocking dielectric layer 52, a memory material layer 54, an optional dielectric material liner 56, and a vertical semiconductor channel 60. A dielectric material liner 56 may laterally surround the vertical semiconductor channel 60. The memory material layer 54 can laterally surround the dielectric material liner 56.

In case a blocking dielectric layer 52 is present in each memory opening fill structure 58, the blocking dielectric layer 52 may be formed on a sidewall of a memory opening 49, and the vertical stack of memory elements (which may comprise portions of the memory material layer 54) may be formed on the blocking dielectric layer 52. In one embodiment, the vertical stack of memory elements comprises portions of a charge storage layer (comprising the memory material layer 54) located at the levels of the sacrificial material layers 42.

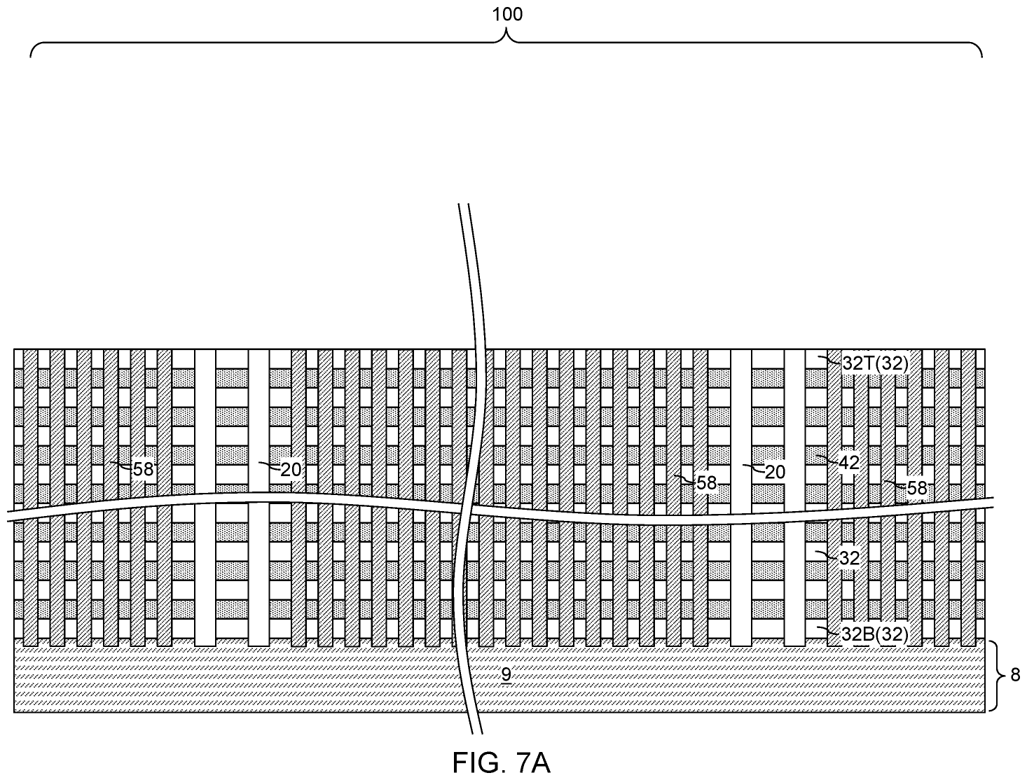

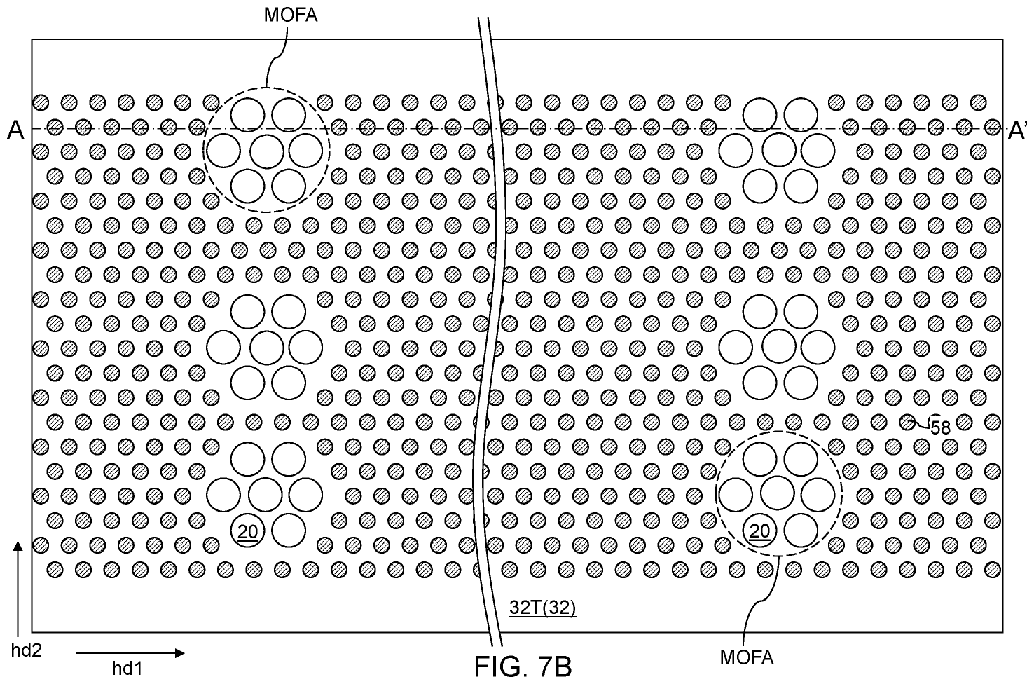

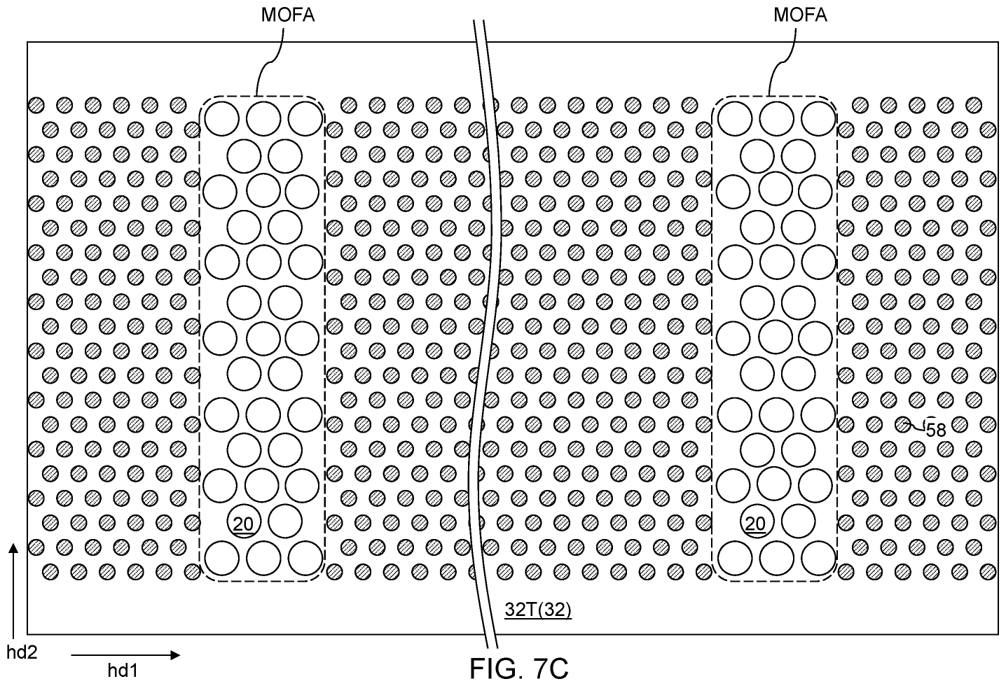

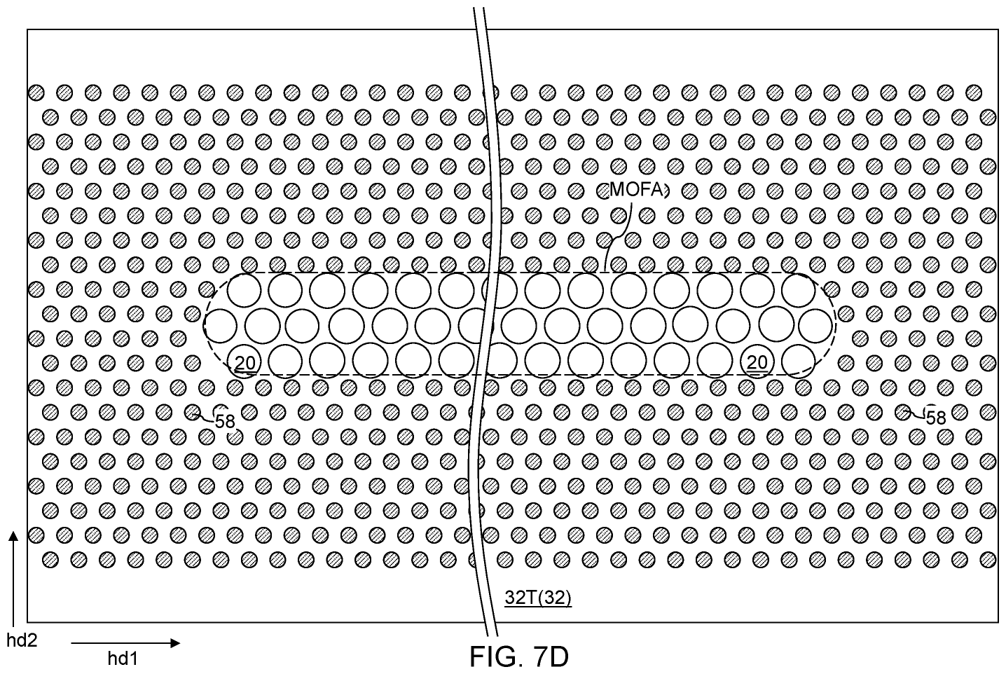

Referring to FIGS. 7A and 7B, the exemplary structure is illustrated after formation of memory opening fill structures 58 and support pillar structures 20 within the memory openings 49 and the support openings 19, respectively. An instance of a memory opening fill structure 58 can be formed within each memory opening 49 of the structure of FIG. 5. An instance of the support pillar structure 20 can be formed within each support opening 19 of the structure of FIG. 5. Alternative memory stack structures including different layer stacks or structures for the memory film 50 and/or for the vertical semiconductor channel 60 may be used instead. In one embodiment, neighboring rows of memory-opening-free areas MOFA may be laterally spaced apart along the second horizontal direction (e.g., bit line direction) hd2 by at least one row of memory opening fill structures 58.

Referring to FIG. 7C, a first alternative configuration of the exemplary structure is illustrated after the processing steps of FIGS. 7A and 7B. The first alternative configuration can be derived from the exemplary structure illustrated in FIGS. 7A and 7B by rearranging the memory opening fill structures 58 and the support pillar structures 20 such that neighboring rows of memory-opening-free-areas MOFA are not laterally spaced apart along the second horizontal direction hd2 by any intervening row of memory opening fill structures 58. In this case, clusters of support pillar structures 20 can be arranged such that each cluster of support pillar structures 20 laterally surrounds at least one memory-opening-free area MOFA. The cluster of support pillar structures 20 laterally extends along the second horizontal direction hd2 between columns of memory opening fill structures 58.

Referring to FIG. 7D, a second alternative configuration of the exemplary structure is illustrated after the processing steps of FIGS. 7A and 7B. The second alternative configuration can be derived from the exemplary structure illustrated in FIGS. 7A and 7B by rearranging the memory opening fill structures 58 and the support pillar structures 20 such that a cluster of support pillar structures 20 encloses a row of memory-opening-free areas MOFA. The cluster of support pillar structures 20 laterally extends along the first horizontal direction hd1 between rows of memory opening fill structures 58.

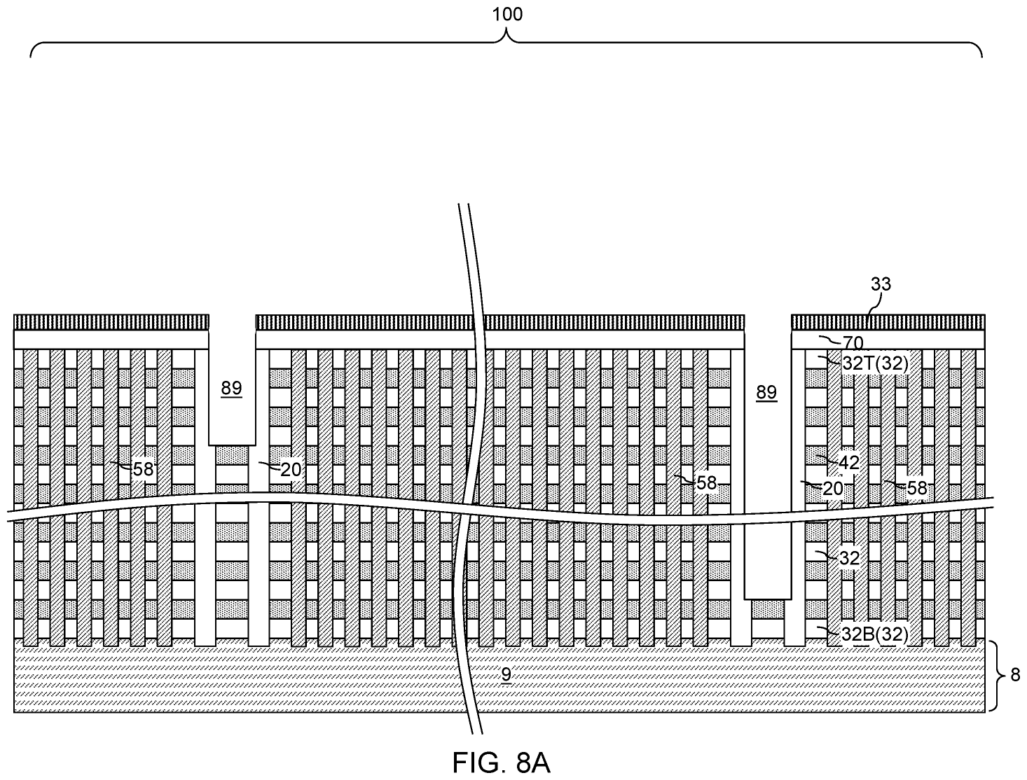

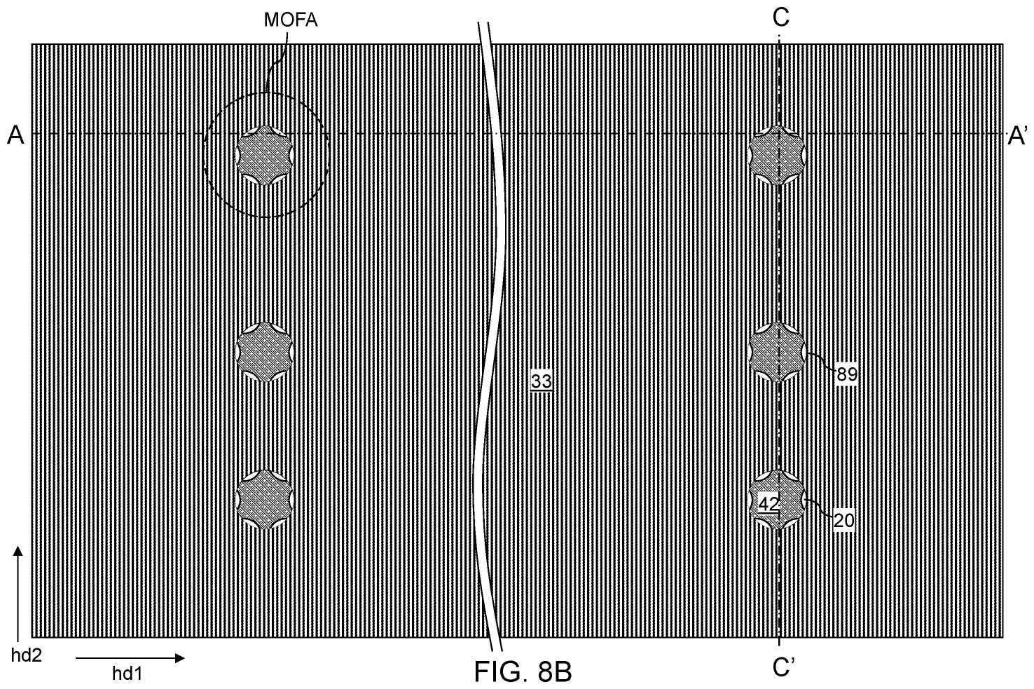

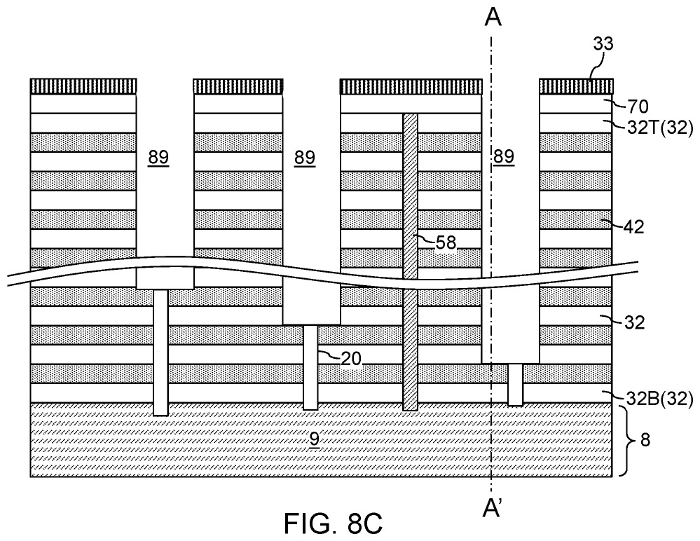

Referring to FIGS. 8A-8C, an insulating cap layer 70 can be formed over the alternating stack (32, 42), the memory opening fill structures 58, and the support pillar structures 20. The insulating cap layer 70 comprises an insulating material, such as silicon oxide, and may have a thickness in a range from 20 nm to 300 nm, although lesser and greater thicknesses may also be employed. Subsequently, contact via cavities 89 having different depths can be formed in the memory-opening-free areas MOFA that are laterally surrounded by a respective cluster of support pillar structures 20. Each of the contact via cavities 89 vertically extends through a respective subset of the layers within the alternating stack (32, 42), and optionally through at least one of the support pillar structures 20. Each of the contact via cavities 89 has a respective bottom surface that includes a segment of a respective sacrificial material layer 42. The respective bottom surface of at least some of the contact via cavities 89 may also include at least a portion of the top surface of an underlying support pillar structure 20.

Generally, the contact via cavities 89 can be formed using any suitable methods. One embodiment method of forming the contact via cavities 89 is described below. In this embodiment, a patterned hard mask layer 33 may be formed over the alternating stack (32, 42). The patterned hard mask layer 33 may comprise any etch mask material that can withstand ashing processes that are subsequently employed to remove patterned photoresist material layers. The patterned hard mask layer 33 may comprise a dielectric metal oxide material, a metallic material, or a semiconductor material, such as amorphous silicon. The patterned hard mask layer 33 may be formed by depositing a blanket (unpatterned) hard mask material layer, by forming a high-fidelity photoresist material layer, such as a deep ultraviolet (DUV) photoresist material layer, over the blanket hard mask material layer, by lithographically patterning the photoresist material layer to form openings in areas in which contact via cavities 89 are to be subsequently formed, and by transferring the pattern in the patterned photoresist layer through the blanket hard mask material layer by performing an anisotropic etch process. An array of openings is formed through the patterned hard mask layer 33. The high-fidelity photoresist material can be subsequently removed.

A series of block-level photoresist layers, such as mid-ultraviolet (MUV) photoresist layers, in combination with a series of anisotropic etch processes can be subsequently employed to sequentially cover a respective subset of the openings in the patterned hard mask layer 33 and to extend the pattern of the openings in the patterned hard mask layer 33 through a respective number of stacks of an insulating layer 32 and a sacrificial material layer 42. For example, about one half of all of the openings through the patterned hard mask layer 33 can be covered by a first block-level photoresist layer, and one insulating layer 32 and one sacrificial material layer 42 can be etched by performing an anisotropic etch process underneath the openings through the unmasked portions of the sacrificial material layer. Any unmasked portion of the support pillar structures 20 may be collaterally etched by selecting the etch chemistry of the various etch steps of an anisotropic etch process such that the overall etch rate for the material of the support pillar structures 20 matches the overall etch rate for a combination of an insulating layers 32 and a sacrificial material layer 42. The first block-level photoresist layer can be subsequently removed. About one half of all of the openings through the patterned hard mask layer 33 can be covered by a second block-level photoresist layer. About one half of the unmasked openings are among the openings previously covered by the first block-level photoresist layer, and the remainder of the unmasked openings are among the openings previously masked by the first block-level photoresist layer. Two pairs of an insulating layer 32 and a sacrificial material layer 42 (i.e., two insulating layers 32 and two sacrificial material layers 42) can be etched by performing an anisotropic etch process underneath the openings through the unmasked portions of the sacrificial material layer. Any unmasked portion of the support pillar structures 20 may be collaterally etched by selecting the etch chemistry of the various etch steps of an anisotropic etch process such that the overall etch rate for the material of the support pillar structures 20 matches the overall etch rate for a combination of an insulating layers 32 and a sacrificial material layer 42. The second block-level photoresist layer can be subsequently removed. The above scheme can be repeated up to the N-th block-level photoresist layer and an N-th anisotropic etch process etching 2^{(N-1)} pairs of an insulating layer 32 and a sacrificial material layer 42. A terminal anisotropic etch process may be performed in the absence of any block-level photoresist layer, for example, to etch through unmasked portions of a respective set of two insulating layers 32 and a sacrificial material layer 42 that underlies any opening through the patterned hard mask layer 33.

Contact via cavities 89 having 2^{N} different depths can be formed in the memory-opening-free areas MOFA. In an illustrative example, if N is 8, the total number of sacrificial material layers 42 may be 2⁸, i.e., 256. The patterned hard mask layer 33 can be subsequently removed, for example, by performing an etch process that removes the material of the patterned hard mask layer 33 selective to the materials of the alternating stack (32, 42).

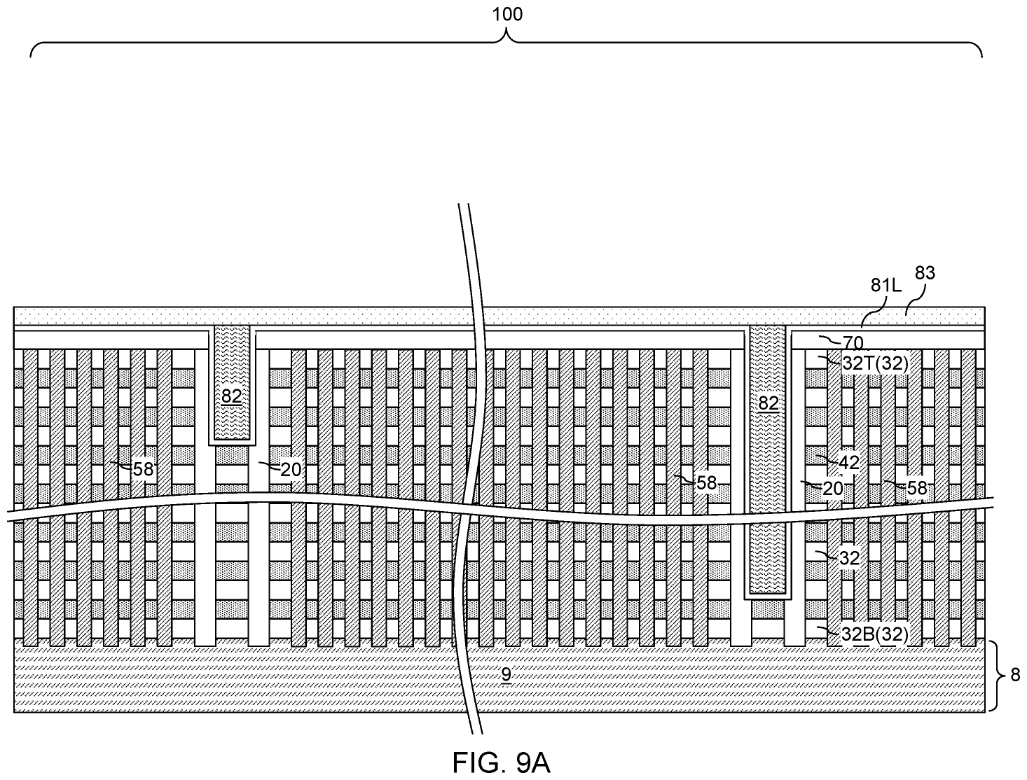

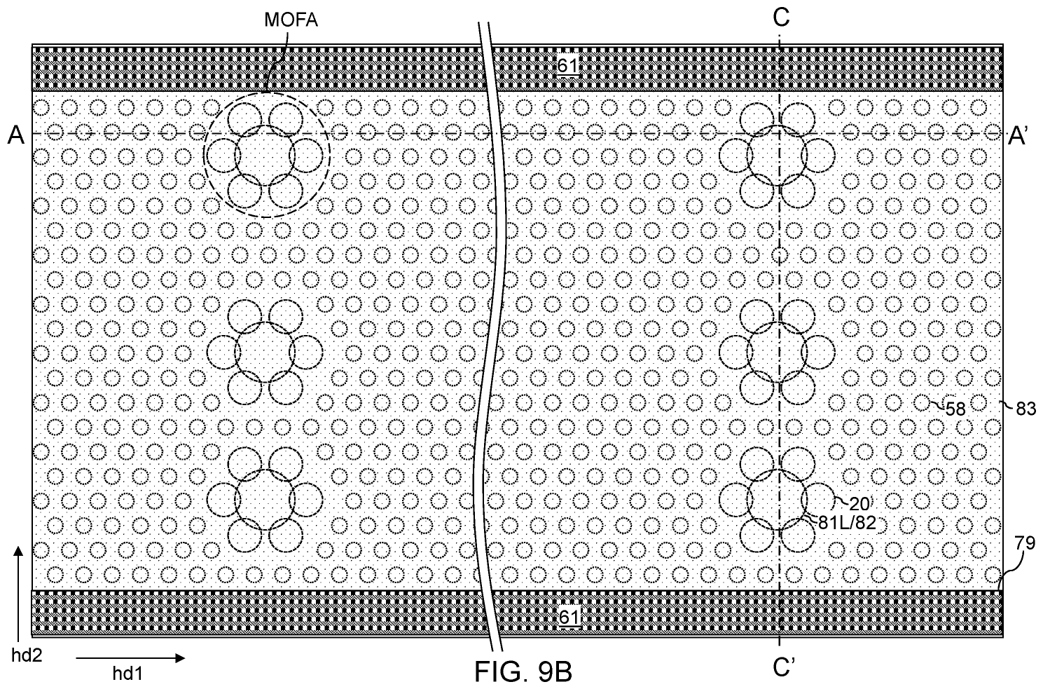

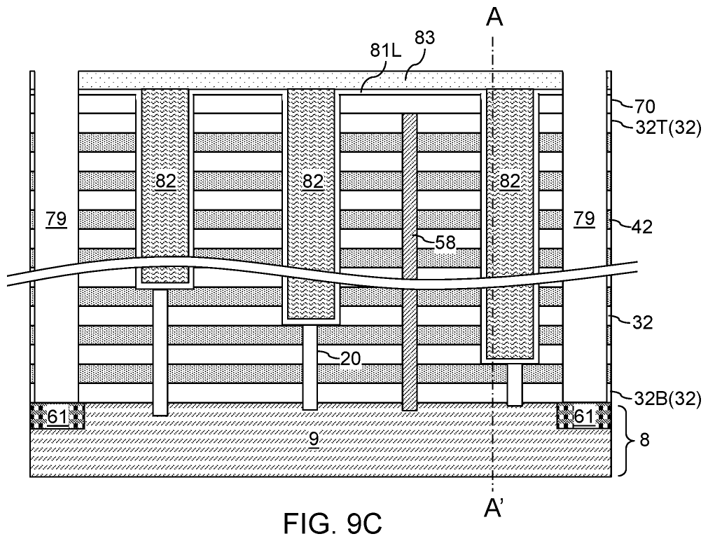

Referring to FIGS. 9A-9C, an insulating material, such as silicon oxide, can be conformally deposited to form an insulating liner layer 81L. The thickness of the insulating liner layer 81L may be in a range from 5 nm to 100 nm, although lesser and greater thicknesses may also be employed.

A sacrificial fill material can be deposited in the voids within the contact via cavities 89. The sacrificial fill material comprises a material that can be subsequently removed selective to materials of the insulating liner layer 81L and the insulating cap layer 70. For example, the sacrificial fill material may comprise a carbon-based material, such as amorphous carbon or diamond-like carbon, a semiconductor material, such as amorphous silicon, polysilicon, or a silicon-germanium alloy, or a dielectric material, such as borosilicate glass or organosilicate glass. Excess potions of the sacrificial fill material may be removed from above the horizontal plane including the top surface of the insulating liner layer 81L employing a planarization process. The planarization process may comprise a recess etch process or a chemical mechanical polishing process. Each remaining portion of the sacrificial fill material constitutes a sacrificial via fill material portion 82.

Generally, contact via cavities 89 having different depths can be formed within the areas of the array of memory-opening-free areas MOFA in a plan view, and the insulating liner layer 81L and a sacrificial via fill material can be formed in the via cavities 89. Portions of the sacrificial via fill material can be removed from above a horizontal plane including a topmost surface of the insulating liner layer 81L. Remaining portions of the sacrificial via fill material constitute the sacrificial via fill material portions 82. In-process via structures including sacrificial via fill material portions 82 can be formed within areas of the array of memory-opening-free areas MOFA in the plan view. Each in-process via structure comprises a respective vertically-extending cylindrical portion of the insulating liner layer 81L and a respective sacrificial via fill material portion 82. Each of the in-process via structures vertically extends through a respective subset of layers within the alternating stack (32, 42).

A sacrificial capping layer 83 may be deposited over the insulating liner layer 81L and the sacrificial via fill material portions 82. The sacrificial capping layer 83 comprises a material that may be subsequently removed. For example, the sacrificial capping layer 83 may comprise a dielectric material, such as silicon oxide, or a semiconductor material such as amorphous silicon. The thickness of the sacrificial capping layer 83 may be in a range from 5 nm to 100 nm, although lesser and greater thicknesses may also be employed.

A photoresist layer (not shown) can be applied over the sacrificial capping layer 83, and is lithographically patterned to form elongated openings in areas between clusters of memory opening fill structures 58, which can be slit shaped areas that are free of any memory opening fill structures 58, any support pillar structures 20, and any sacrificial via fill material portions 82. The pattern in the photoresist layer can be transferred through the sacrificial capping layer 83, the insulating liner layer 81L, and the alternating stack (32, 42) employing an anisotropic etch to form lateral isolation trenches 79. The lateral isolation trenches 79 vertically extend from the top surface of the sacrificial capping layer 83 to the top surface of the substrate 8. The lateral isolation trenches 79 laterally extend along the first horizontal direction hd1 between neighboring memory blocks of memory opening fill structures 58.

In one embodiment, the lateral isolation trenches 79 can laterally extend along the first horizontal direction (e.g., word line direction) hd1 and can be laterally spaced apart from each other along the second horizontal direction hd2 (which may be a bit line direction) that is perpendicular to the first horizontal direction hd1. The memory opening fill structures 58 can be arranged in rows that extend along the first horizontal direction hd1. Multiple rows of memory opening fill structures 58 can be located between each neighboring pair of lateral isolation trenches 79 in a respective memory block. Thus, the lateral isolation trenches 79 separate adjacent memory blocks along the second horizontal direction hd2. Generally, lateral isolation trenches 79 laterally extending along the first horizontal direction hd1 can be formed through the vertically alternating sequence of insulating layers 32 and sacrificial material layers 42. The lateral isolation trenches 79 are laterally spaced apart along the second horizontal direction hd2.

For each set of sacrificial via fill material portions 82 that are arranged along the first horizontal direction hd1, a first lateral isolation trench 79 and a second lateral isolation trench 79 that laterally extend along the first horizontal direction hd1 and laterally spaced apart along the second horizontal direction hd2 through the alternating stack (32, 42) can be formed such that the set of sacrificial via fill material portions 82 is located between the first lateral isolation trench 79 and the second lateral isolation trench 79.

Dopants of the second conductivity type can be implanted into surface portions of the semiconductor material layer 9 that are physically exposed underneath the lateral isolation trenches 79. Source regions 61 having a doping of the second conductivity type can be formed underneath the lateral isolation trenches 79. The photoresist layer can be removed, for example, by ashing.

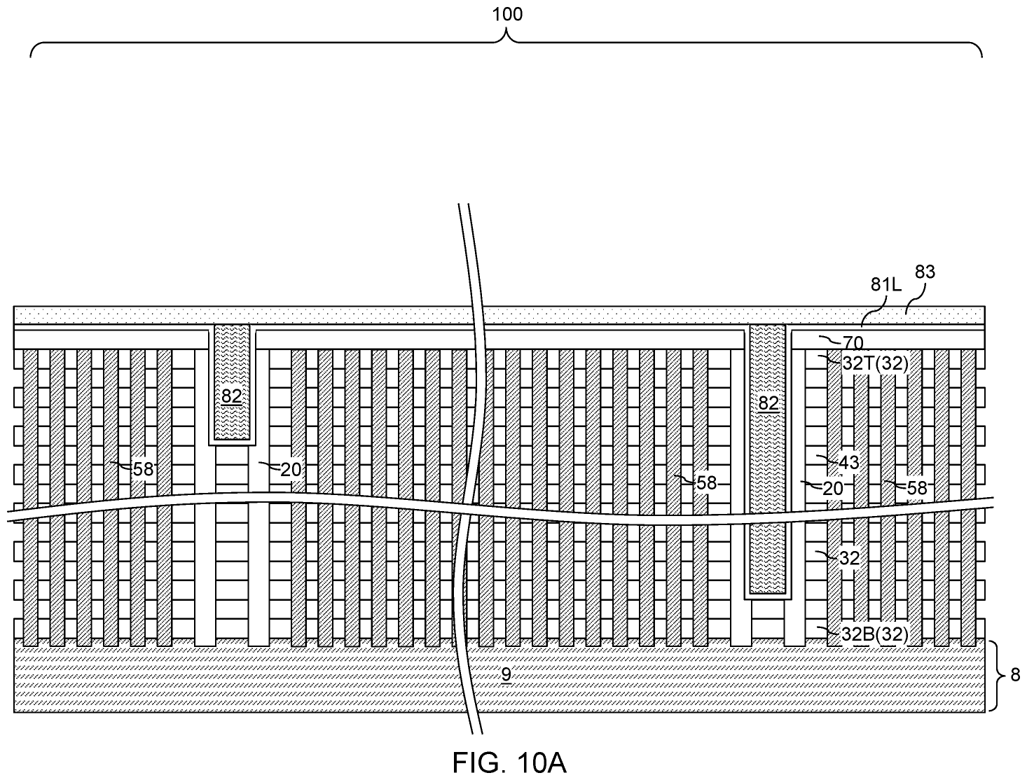

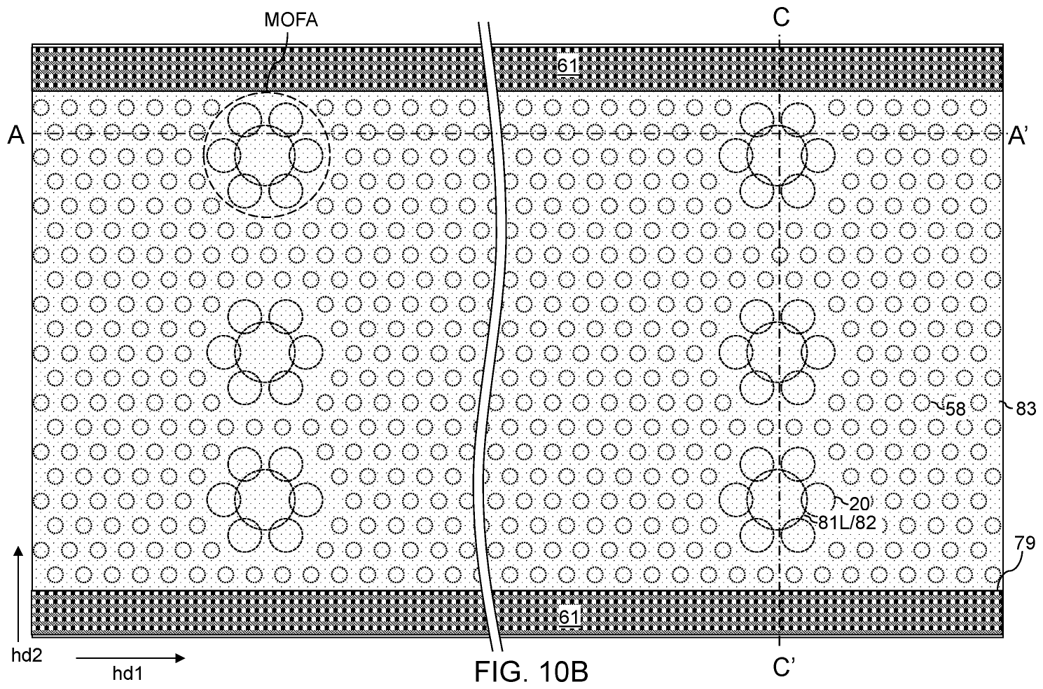

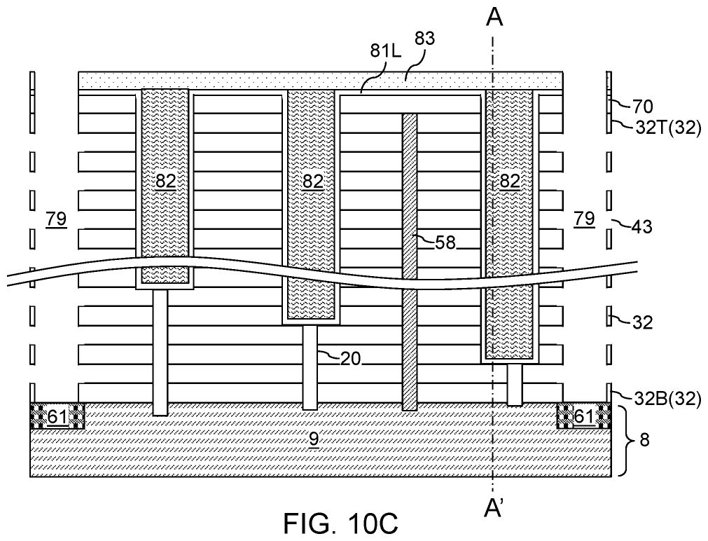

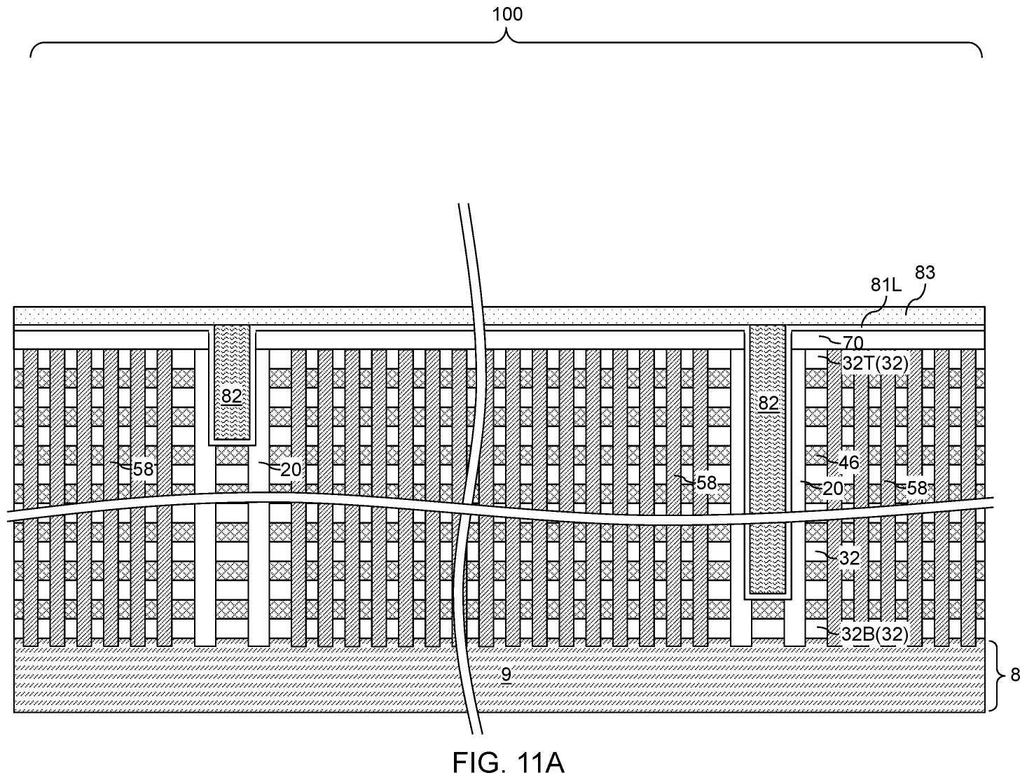

Referring to FIG. 10A-10C, an etchant that selectively etches the materials of the sacrificial material layers 42 with respect to the materials of the insulating layers 32 and the material of the outermost layer of the memory films 50 and the insulating liner layer 81L can be introduced into the lateral isolation trenches 79, for example, employing an isotropic etch process. For example, the sacrificial material layers 42 can include silicon nitride, the materials of the insulating layers 32 and the insulating liner layer 81L and the material of the outermost layer of the memory films 50 can include silicon oxide. Backside recesses 43 are formed in volumes from which the sacrificial material layers 42 are removed. For each set of sacrificial via fill material portions 82 located in the same memory block between a first lateral isolation trench 79 and a second lateral isolation trench 79, the sacrificial material layers 42 between the first lateral isolation trench 79 and the second lateral isolation trench 79 can be removed by providing an isotropic etchant into the first lateral isolation trench 79 and the second lateral isolation trench 79.

The isotropic etch process can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art.

Each of the backside recesses 43 can be a laterally extending cavity having a lateral dimension that is greater than the vertical extent of the cavity. In other words, the lateral dimension of each of the backside recesses 43 can be greater than the height of the respective backside recess 43. Each of the backside recesses 43 can laterally extend substantially parallel to the top surface of the substrate 8. A backside recess 43 can be vertically bounded by a top surface of an underlying insulating layer 32 and a bottom surface of an overlying insulating layer 32. In one embodiment, each of the backside recesses 43 can have a uniform height throughout. A plurality of backside recesses 43 is formed at each level of the sacrificial material layer 42. The plurality of backside recesses 43 are laterally spaced apart from each other by the lateral isolation trenches 79.

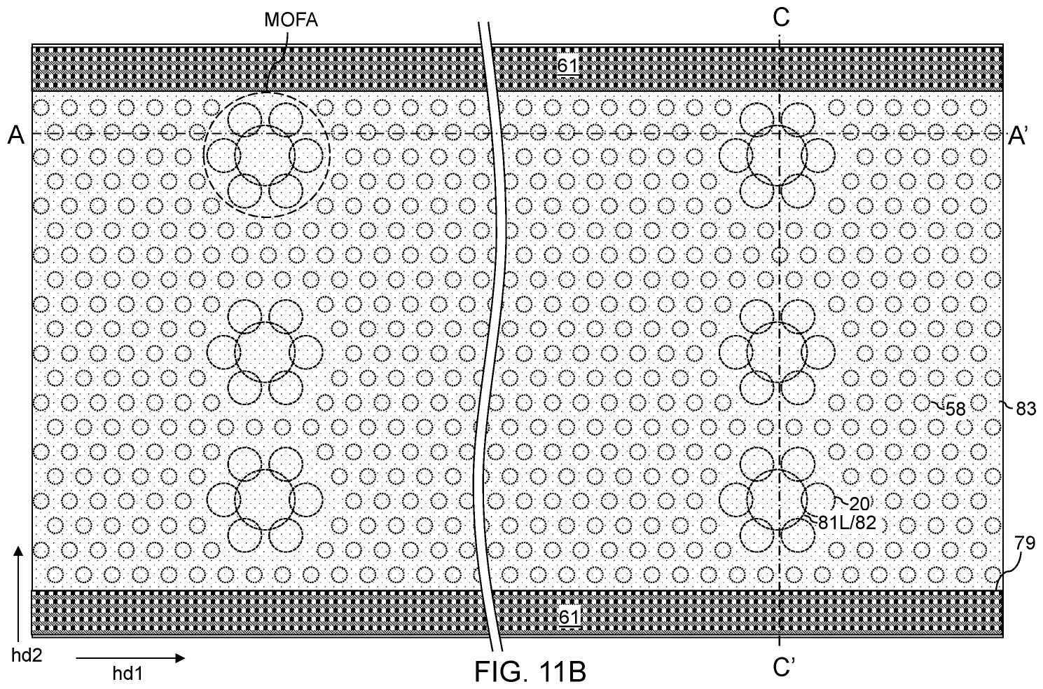

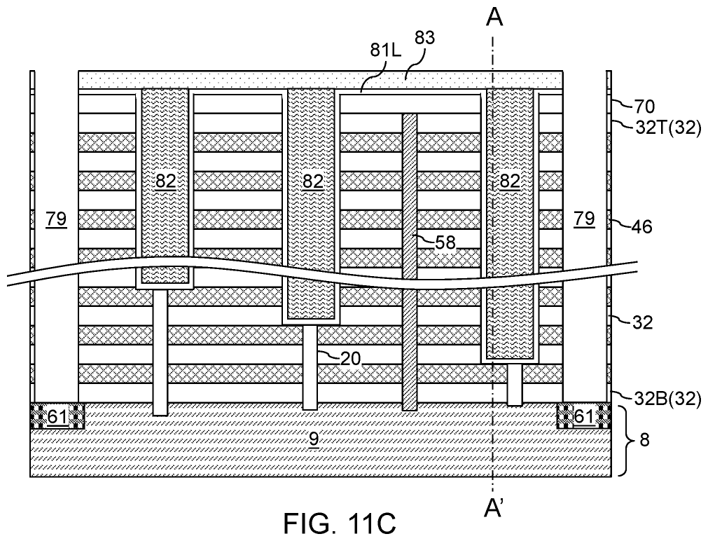

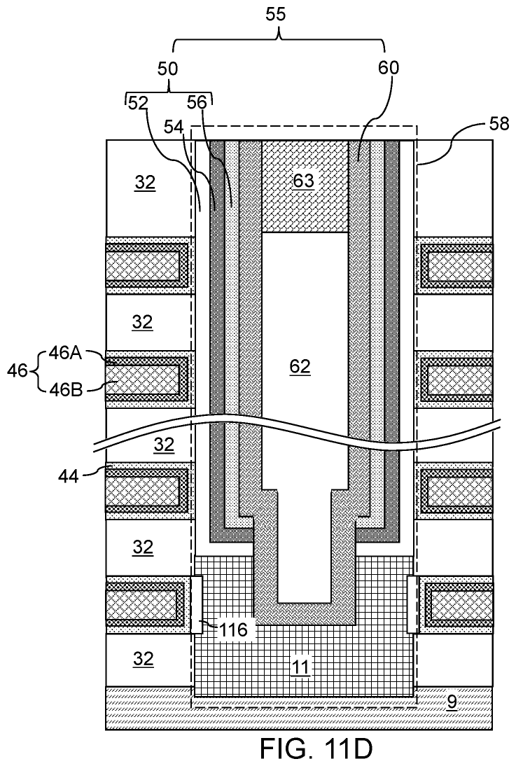

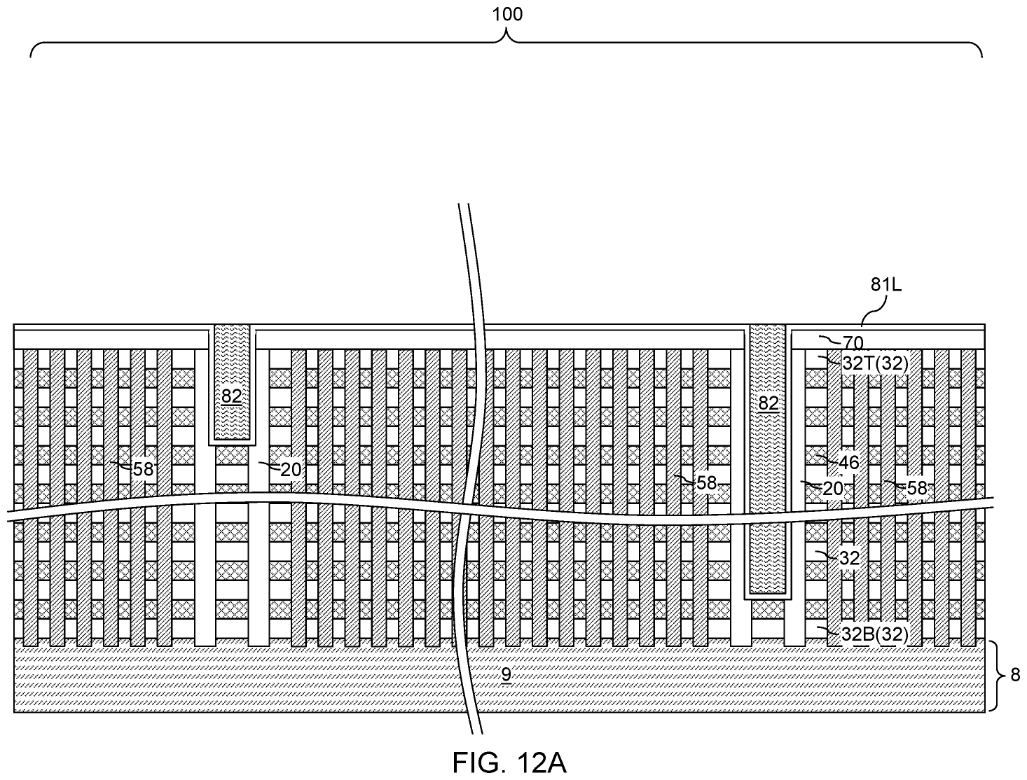

Referring to FIGS. 11A-11D, an optional backside blocking dielectric layer 44 can be optionally deposited in the backside recesses 43 and the lateral isolation trenches 79 and over the sacrificial capping layer 83. The backside blocking dielectric layer 44, if employed, comprises a dielectric metal oxide such as aluminum oxide, a dielectric oxide of at least one transition metal element, a dielectric oxide of at least one Lanthanide element, a dielectric oxide of a combination of aluminum, at least one transition metal element, and/or at least one Lanthanide element. Alternatively or additionally, the backside blocking dielectric layer 44 can include a silicon oxide layer. The backside blocking dielectric layer 44 can be deposited by a conformal deposition method such as chemical vapor deposition or atomic layer deposition. The backside blocking dielectric layer 44 can be formed on the sidewalls of the lateral isolation trenches 79 and the insulating liner layer 81L, horizontal surfaces and sidewalls of the insulating layers 32, the portions of the sidewall surfaces of the memory opening fill structures 58 that are physically exposed to the backside recesses 43. A backside cavity is present within the portion of each lateral isolation trench 79 that is not filled with the backside blocking dielectric layer 44.

A metallic barrier liner 46A can be deposited in the backside recesses 43, peripheral portions of the lateral isolation trenches 79, and over the sacrificial capping layer 83. The metallic barrier liner 46A includes an electrically conductive metallic material that can function as a diffusion barrier layer and/or adhesion promotion layer for a metallic fill material to be subsequently deposited. The metallic barrier liner 46A can include a conductive metallic nitride material such as TiN, TaN, WN, or a stack thereof, or can include a conductive metallic carbide material such as TiC, TaC, WC, or a stack thereof. In one embodiment, the metallic barrier liner 46A can be deposited by a conformal deposition process such as chemical vapor deposition (CVD) or atomic layer deposition (ALD). The thickness of the metallic barrier liner 46A can be in a range from 2 nm to 8 nm, such as from 3 nm to 6 nm, although lesser and greater thicknesses can also be employed. In one embodiment, the metallic barrier liner 46A can consist essentially of a conductive metal nitride such as TiN.

A metal fill material is deposited in the plurality of backside recesses 43, on the sidewalls of the at least one the lateral isolation trench 79, and over the top surface of the sacrificial capping layer 83 to form a metallic fill material portion 46B. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material portion 46B can consist essentially of at least one elemental metal. The at least one elemental metal of the metallic fill material portion 46B can be selected, for example, from tungsten, cobalt, ruthenium, titanium, and tantalum. In one embodiment, the metallic fill material portion 46B can consist essentially of a single elemental metal. In one embodiment, the metallic fill material portion 46B can be deposited employing a fluorine-containing precursor gas such as WF₆. In one embodiment, the metallic fill material portion 46B can be a tungsten layer including a residual level of fluorine atoms as impurities. The metallic fill material portion 46B is spaced from the insulating layers 32 and the memory opening fill structures 58 by the metallic barrier liner 46A, which is a metallic barrier layer that blocks diffusion of fluorine atoms therethrough.

Generally, for each set of of sacrificial via fill material portions 82 located in the same memory block between a first lateral isolation trench 79 and a second lateral isolation trench 79, electrically conductive layers 46 are formed by providing a precursor gas for a conductive material in the electrically conductive layers 46 into the first lateral isolation trench 79 and the second lateral isolation trench 79.

An etch back process can be performed to remove portions of the metallic fill material portion 46B and the metallic barrier liner 46A from inside the lateral isolation trenches 79 and from above the sacrificial capping layer 83. The etch back process may comprise an isotropic etch process and/or an anisotropic etch process. Each combination of a remaining portion of the metallic barrier liner 46A and a remaining portion of the metallic fill material portion 46B that remain in a respective backside recess 43 constitutes an electrically conductive layer 46. The backside blocking dielectric layer may or may not remain in the lateral isolation trenches 79.

Each electrically conductive layer 46 includes a portion of the metallic barrier liner 46A and a portion of the metallic fill material portion 46B that are located between a vertically neighboring pair of dielectric material layers such as a pair of insulating layers 32. Each sacrificial material layer 42 can be replaced with an electrically conductive layer 46. Generally, an alternating stack (32, 46) of insulating layers 32 and electrically conductive layers 46 can be formed over the substrate 8.

An alternating stack (32, 46) of the insulating layers 32 and electrically conductive layers 46 is formed within each memory block located between a neighboring pair of the lateral isolation trenches 79 upon formation of the electrically conductive layers 46. In one embodiment, the lateral extent of each of the electrically conductive layers 46 may be the same as the lateral spacing between a neighboring pair of lateral isolation trenches 79 throughout the entirety of each of the electrically conductive layers 46.

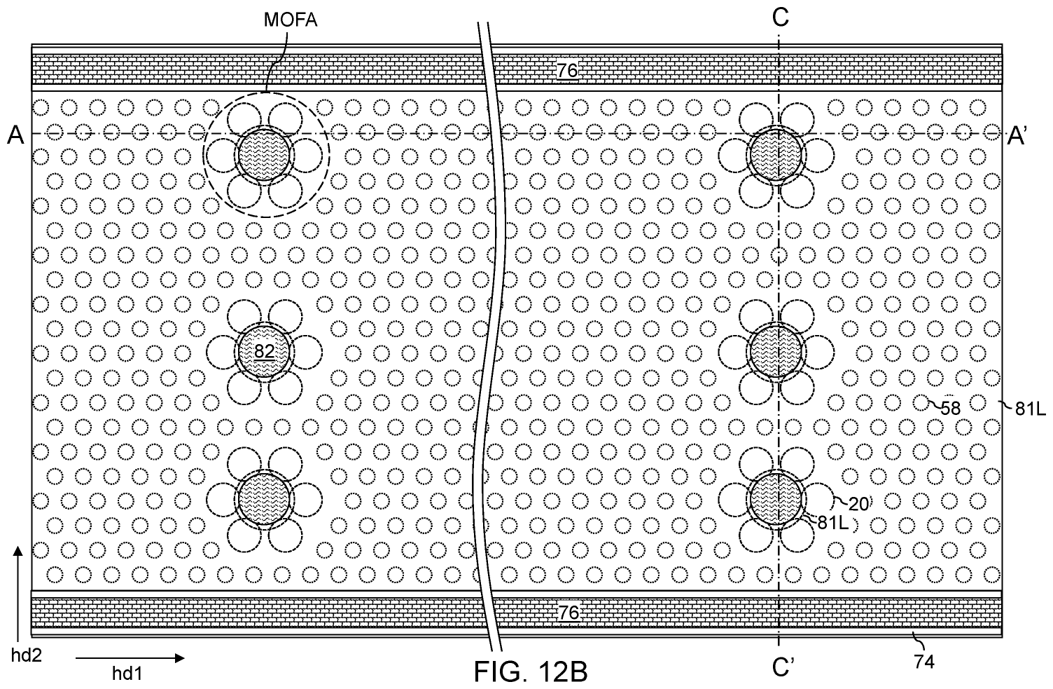

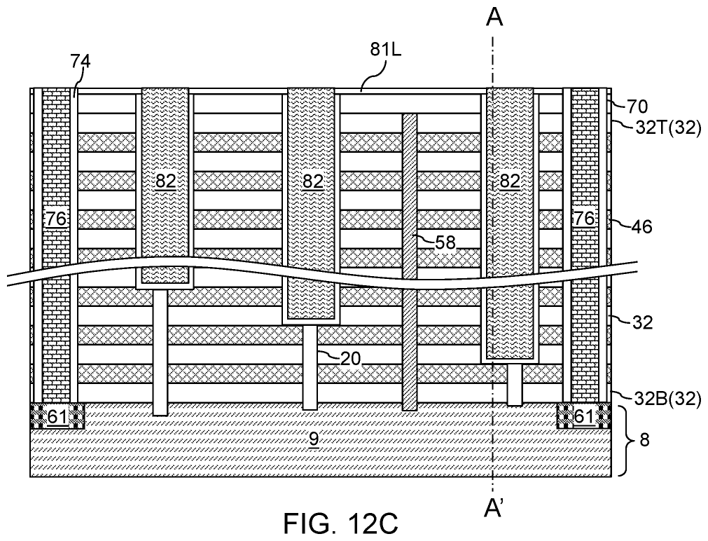

Referring to FIGS. 12A-112C, an insulating material layer can be formed in the lateral isolation trenches 79 and over the sacrificial capping layer 83 by a conformal deposition process. Exemplary conformal deposition processes include, but are not limited to, chemical vapor deposition and atomic layer deposition. The insulating material layer includes an insulating material such as silicon oxide, silicon nitride, a dielectric metal oxide, an organosilicate glass, or a combination thereof. In one embodiment, the insulating material layer can include silicon oxide. The insulating material layer can be formed, for example, by low pressure chemical vapor deposition (LPCVD) or atomic layer deposition (ALD). The thickness of the insulating material layer can be in a range from 1.5 nm to 60 nm, although lesser and greater thicknesses can also be employed.

An anisotropic etch is performed to remove horizontal portions of the insulating material layer from above the sacrificial capping layer 83 and at the bottom of each lateral isolation trench 79. Each remaining portion of the insulating material layer constitutes an insulating spacer 74, which may have a generally tubular configuration. A backside cavity is present within a volume surrounded by each insulating spacer 74.

A backside contact via structure 76 can be formed within each backside cavity. Each backside contact via structure 76 can fill a respective cavity. Each contact via structures 76 can be formed by depositing at least one conductive material in a remaining unfilled volume (i.e., a backside cavity) of the lateral isolation trenches 79. For example, the at least one conductive material can include a conductive liner and a conductive fill material portion. The conductive liner can include a conductive metallic liner such as TiN, TaN, WN, TiC, TaC, WC, an alloy thereof, or a stack thereof. The thickness of the conductive liner can be in a range from 3 nm to 30 nm, although lesser and greater thicknesses can also be employed. The conductive fill material portion can include a metal or a metallic alloy. For example, the conductive fill material portion can include W, Cu, Al, Co, Ru, Ni, an alloy thereof, or a stack thereof.

The at least one conductive material can be planarized employing the insulating liner layer 81L as a stopping layer. If chemical mechanical planarization (CMP) process is employed, the horizontally-extending portion of the insulating liner layer 81L can be employed as a CMP stopping layer. A horizontally-extending portion of the at least one conductive material and the sacrificial capping layer 83 can be removed from above the horizontal plane including the top surface of the horizontally-extending portion of the insulating liner layer 81L. Each remaining continuous portion of the at least one conductive material in the lateral isolation trenches 79 constitutes a backside contact via structure 76. Each contiguous combination of an insulating spacer 74 and a backside contact via structure 76 constitutes a lateral isolation trench fill structure (74, 76). Top surfaces of the sacrificial via fill material portions 82 can be physically exposed after the planarization process.

An alternating stack of insulating layers 32 and electrically conductive layers 46 can be contacted by a first lateral isolation trench fill structure (74, 76) and a second lateral isolation trench fill structure (74, 76). The first lateral isolation trench fill structure (74, 76) may have a first dielectric sidewall that laterally extends along the first horizontal direction hd1, and may contact each of the insulating layers 32 and the electrically conductive layers 46 within the alternating stack (32, 46). The second lateral isolation trench fill structure (74, 76) may be laterally spaced from the first lateral isolation trench fill structure (74, 76) along the second horizontal direction hd2, may have a second dielectric sidewall that laterally extends along the first horizontal direction hd1, and may contact each of the insulating layers 32 and the electrically conductive layers 46 within the alternating stack (32, 46).

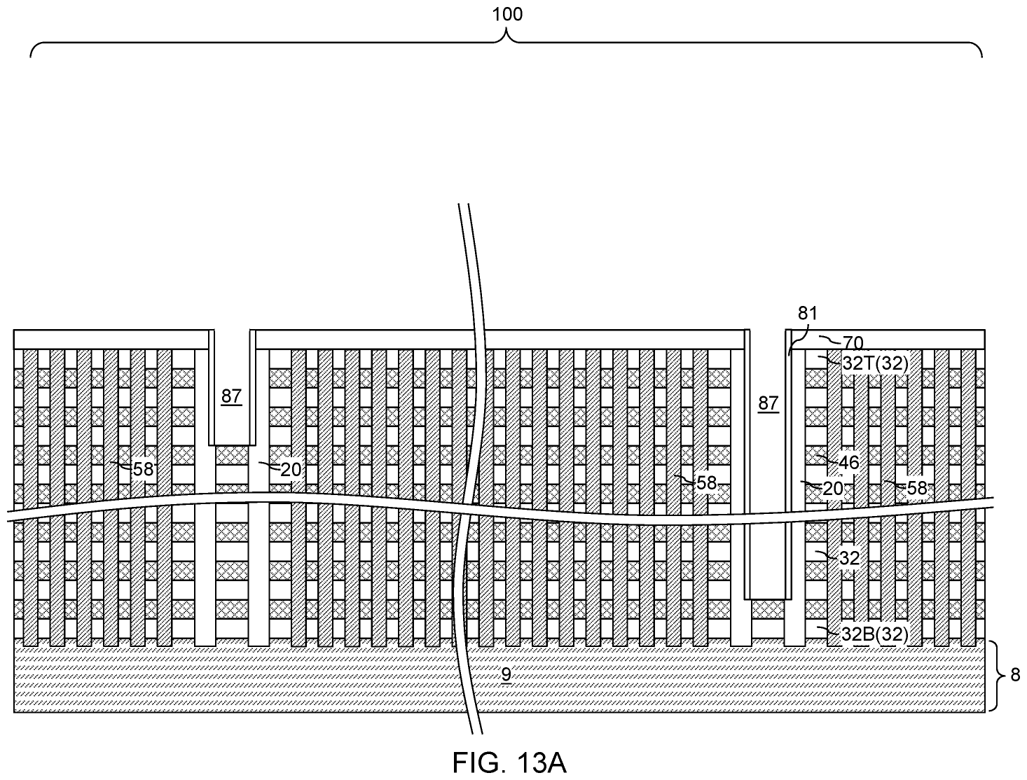

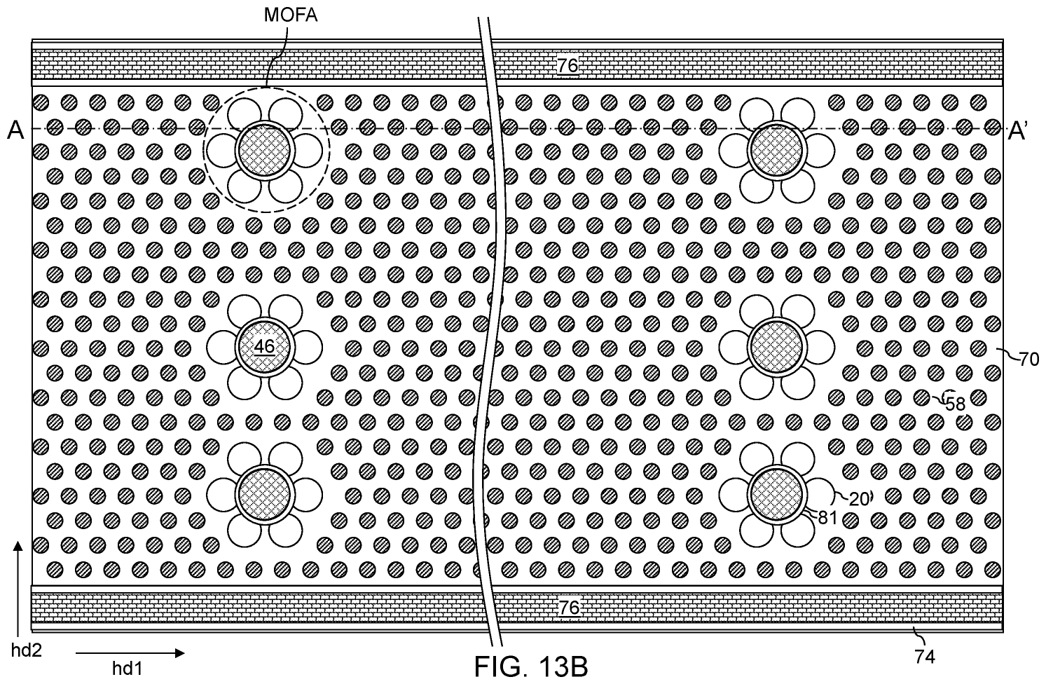

Referring to FIGS. 13A-13B, the sacrificial via fill material portions 82 can be removed selective to the material of the insulating liner layer 81L. For example, a selective etch process or an ashing process (if the sacrificial via fill material portions 82 comprise a carbon material) may be employed to remove the sacrificial via fill material portions 82. If a selective etch process is employed, the selective etch process may comprise an isotropic etch process or an anisotropic etch process. A via cavity 87 is formed in each volume from which a sacrificial via fill material portion 82 is removed.

An anisotropic etch process can be subsequently performed to remove horizontally-extending portions of the insulating liner layer 81L that overlie the insulating cap layer 70 or underlie a respective via cavity 87. Each remaining tubular portion of the insulating liner layer 81L constitutes an insulating spacer 81, which is also referred to as a tubular insulating spacer 81 or an insulating via spacer 81. If a backside blocking dielectric layer 44 is employed, the anisotropic etch process can remove physically exposed portions of the blocking dielectric layer 44 underneath each via cavity 87 so that surfaces of the electrically conductive layers 46 are physically exposed underneath the via cavities 87. Each via cavity 87 can be laterally surrounded by a respective insulating spacer 81. Each of the electrically conductive layers 46 may comprise at least one physically exposed surface segment (e.g., top surface segment) that underlies a respective via cavity 87.

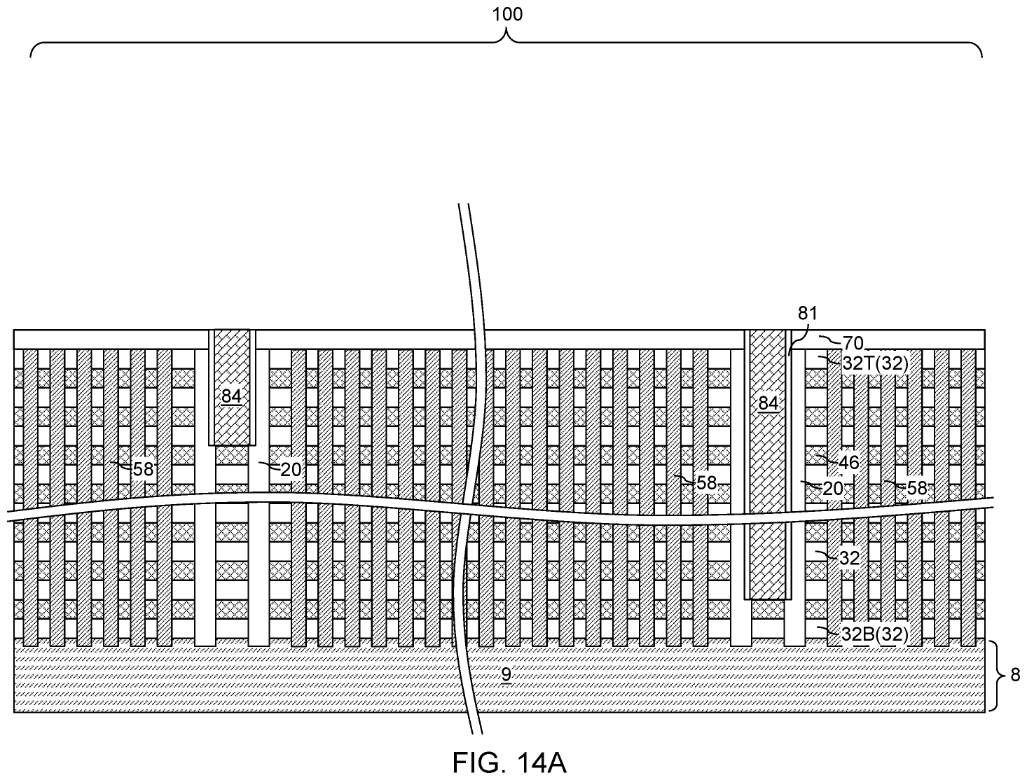

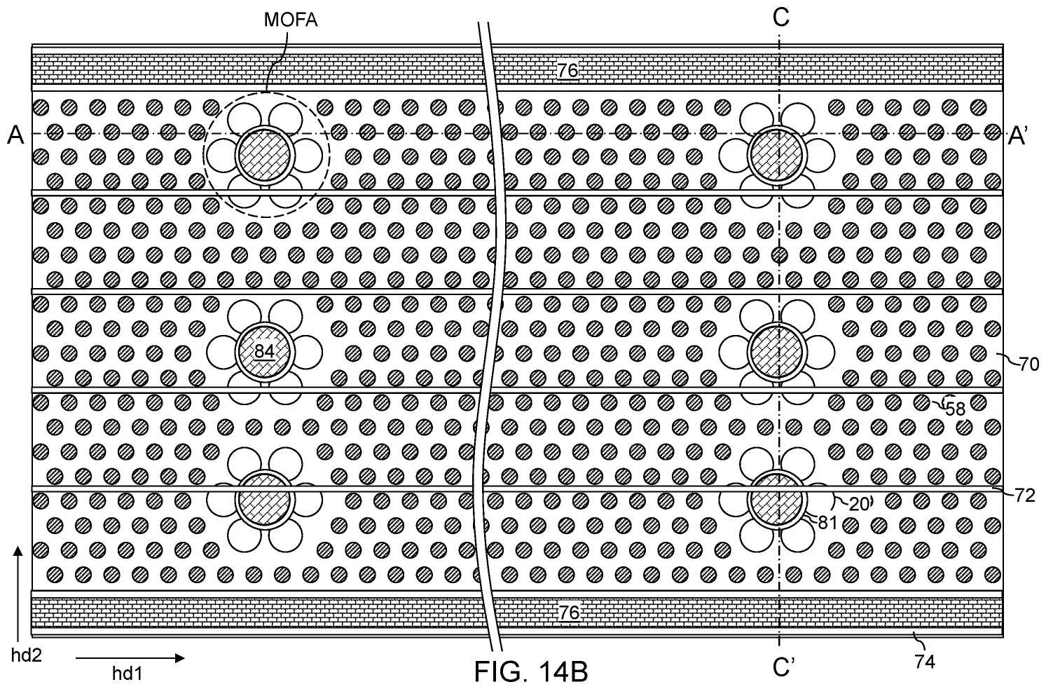

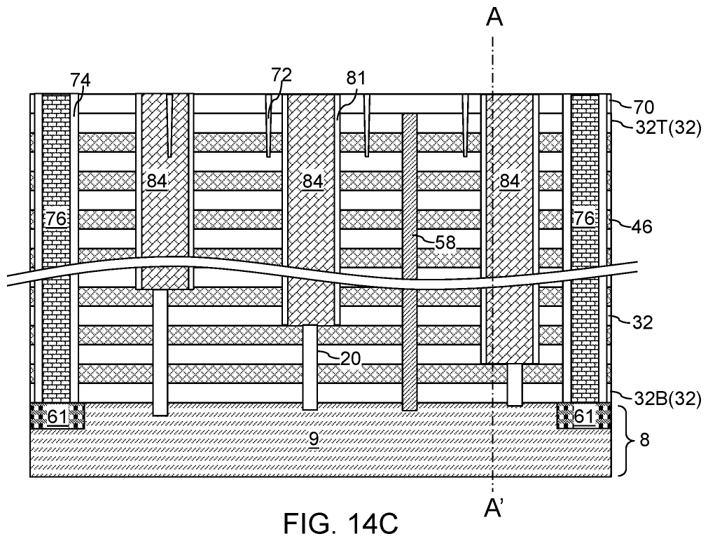

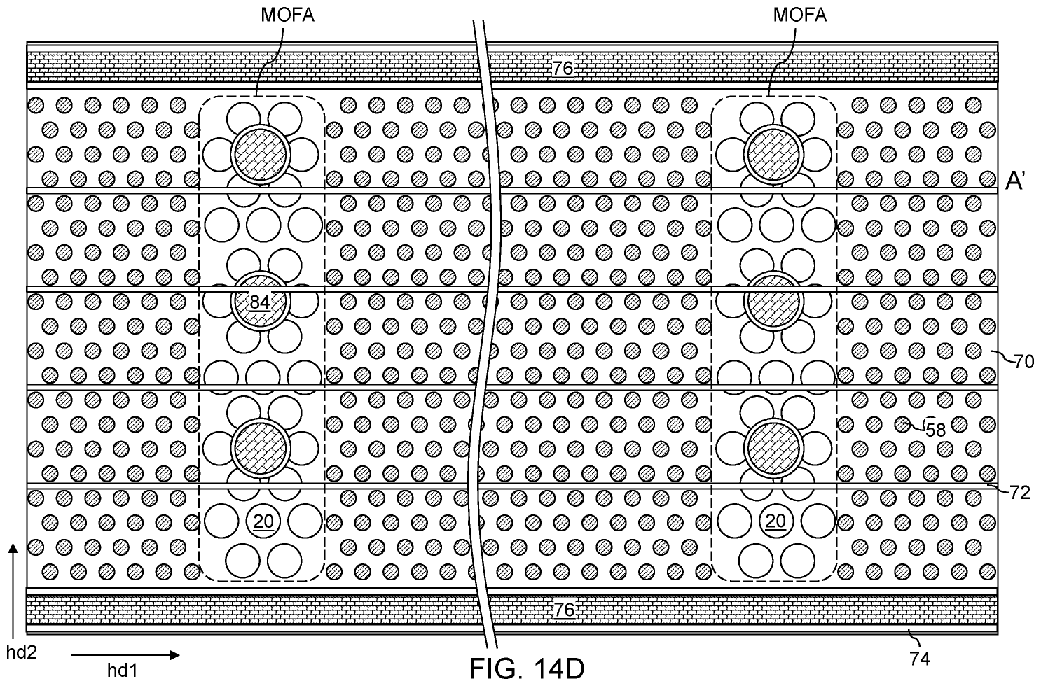

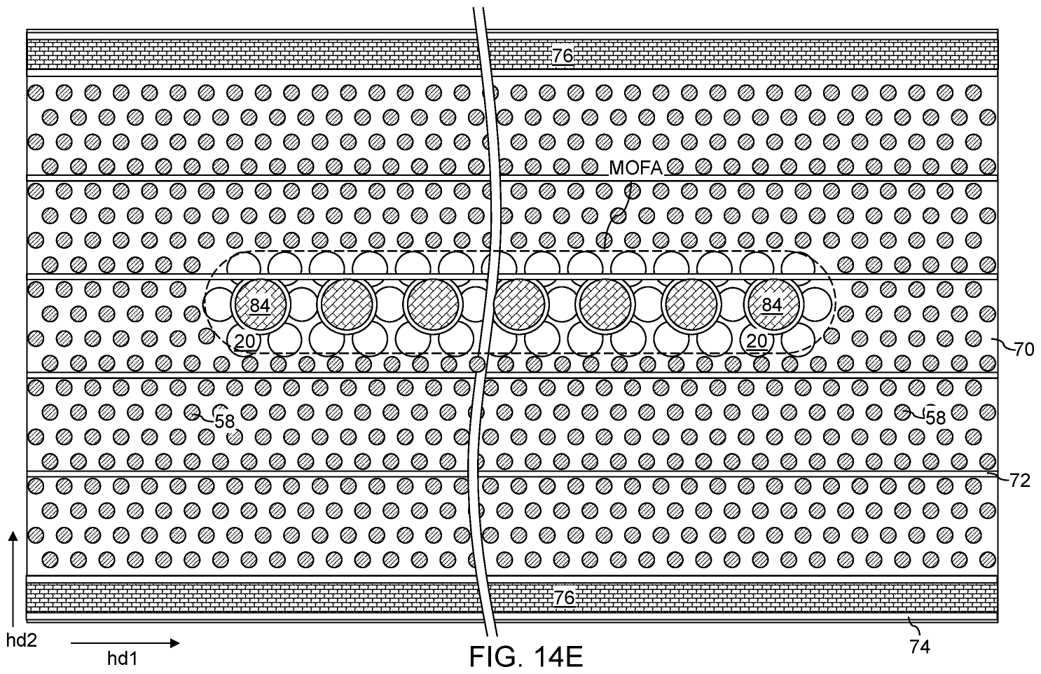

Referring to FIGS. 14A-14C, at least one conductive material can be deposited in the via cavities 87. The at least one conductive material may comprise a metallic barrier material and a metallic fill material. The metallic barrier material may comprise a metallic nitride material such as TiN, TaN, and/or WN and/or a metallic carbide material such as TiC, TaC, and/or WC. The metallic fill material may comprise W, Ti, Ta, Ru, Co, Mo, Cu, etc. The at least one conductive material may be deposited by chemical vapor deposition, physical vapor deposition, electroplating, electroless plating, or combinations thereof. Excess portions of the at least one conductive material can be removed from above the horizontal plane including the top surface of the insulating cap layer 70 by performing a planarization process, which may employ a chemical mechanical polishing (CMP) process or a recess etch process. Each remaining portion of the at least one conductive material filling a respective via cavity 87 constitutes a layer contact via structure 84 that contacts top surface a respective electrically conductive layer 46. Each layer contact via structure 84 may be laterally surrounded by a respective insulating spacer 81. Each combination of a layer contact via structure 84 and a respective insulating spacer 81 comprises a layer contact assembly (81, 84).

Thus, the sacrificial via fill material portions 82 can be replaced with the layer contact via structures 84 to form the layer contact assemblies (81, 84). Each of the layer contact assemblies (81, 84) comprises a respective layer contact via structure 84 contacting a respective one of the electrically conductive layers 46 and further comprises a respective insulating spacer 81 that laterally surrounds the respective layer contact via structure 84. An array of layer contact assemblies (81, 84) can be formed within the areas of the array of memory-opening-free areas MOFA in a plan view. The array of layer contact assemblies (81, 84) contains an array of layer contact via structures 84.

In one embodiment having the configuration shown in FIG. 14B, the array of layer contact via structures 84 comprises at least one row of layer contact via structures 84 that are arranged along the first horizontal direction hd1 and laterally spaced apart from each other by subarrays of memory opening fill structures 58. As used herein, a “subarray” is a portion of an array. Thus, each of the subarrays includes a respective subset of the array of memory opening fill structures 58.

In one embodiment shown in FIG. 14C, the array of layer contact assemblies (81, 84) comprises multiple rows of layer contact assemblies (81, 84). In one embodiment, each row of layer contact assemblies (81, 84) within the multiple rows of layer contact assemblies (81, 84) comprises a respective plurality of layer contact assemblies (81, 84) that are arranged along the first horizontal direction hd1. The multiple rows of layer contact assemblies (81, 84) are laterally spaced apart from each other along the second horizontal direction hd2. In one embodiment, the array of memory opening fill structures 58 comprises at least one row of memory opening fill structures 58 that laterally extends along the first horizontal direction hd1 and located between a respective neighboring pair of rows of layer contact assemblies (81, 84) within the multiple rows of layer contact assemblies (81, 84).

In an alternative embodiment shown in FIG. 14E having the second alternative configuration of the exemplary structure based on the layout the memory-opening-free areas MOFA of FIG. 7D, the array of layer contact assemblies (81, 84) comprises a single row of layer contact assemblies (81, 84) per memory block.

In one embodiment, the alternating stack (32, 46) in each memory block comprises a pair of lengthwise sidewalls that laterally extend along the first horizontal direction hd1 between the lateral separation trenches 79, and vertically extend from a bottommost layer of the alternating stack (32, 46) to a topmost layer of the alternating stack (32, 46). The array of memory-opening-free areas MOFA is laterally spaced from a lengthwise sidewall of the pair of lengthwise sidewalls by at least one row of memory opening fill structures 58 that is a subset of the array of memory opening fill structures 58 and that laterally extends along the first horizontal direction hd1.

In another alternative embodiment shown in FIG. 14D having the first alternative configuration of the exemplary structure based on the layout the memory-opening-free areas MOFA of FIG. 7C, the array of layer contact assemblies (81, 84) comprises multiple columns of layer contact assemblies (81, 84) that are arranged along the second horizontal direction hd2 in each memory block.

A photoresist layer can be applied over the insulating cap layer 70, and can be lithographically patterned to form elongated openings that are located between a respective neighboring pair of memory opening fill structures 58. An anisotropic etch process can be performed to transfer the pattern of the elongated openings in the photoresist layer through portions of the insulating cap layer 70, a subset of the electrically conductive layers 46 including the topmost electrically conductive layer 46 within each alternating stack (32, 46), and optionally through a subset of the layer contact via structures 84. Generally, the total number of electrically conductive layers 46 that are cut underneath a respective opening in the photoresist layer can be the same as the total number of drain select levels at which the divided portions of the electrically conductive layers 46 function as drain-select-level electrodes. The elongated trenches that are formed by the anisotropic etch process are herein referred to as drain-select-level isolation trenches. The photoresist layer can be subsequently removed, for example, by ashing.

A dielectric fill material, such as silicon oxide, can be deposited in the drain-select-level isolation trenches. A recess etch process may be performed to remove a horizontally-extending portion of the dielectric fill material from above the insulating cap layer 70. Each portion of the dielectric fill material that fills a respective drain-select-level isolation trench constitutes a drain-select-level dielectric isolation structure 72. Generally, the drain-select-level dielectric isolation structures 72 laterally extend along the first horizontal direction hd1 with a lateral extent that is greater than the maximum lateral extent of the array of memory opening fill structures 58 along the first horizontal direction hd1. Thus, the lateral extent of the drain-select-level dielectric isolation structures 72 along the first horizontal direction hd1 can be greater than the maximum lateral extent of the array of layer contact via structures 84 located within an alternating stack (32, 46) of insulating layers 32 and electrically conductive layers 46. The drain-select-level dielectric isolation structures 72 vertically extend through at least one electrically conductive layer 46 including the topmost electrically conductive layer 46 (e.g., through the drain side select gate electrodes) within the alternating stack (32, 46).

In one embodiment, the array of layer contact assemblies (81, 84) comprises a row of layer contact assemblies (81, 84) that are arranged along first horizontal direction hd1; and the row of layer contact assemblies (81, 84) is laterally spaced from at least one row of memory opening fill structures 58 within the array of memory opening fill structures 58 by one of the drain-select-level dielectric isolation structures 72. In one embodiment, the array of layer contact assemblies (81, 84) comprises a row of layer contact assemblies (81, 84) that are arranged along first horizontal direction hd1; and one of the drain-select-level dielectric isolation structures 72 extends through an upper portion of each layer contact assembly within the row of layer contact assemblies (81, 84).

In one embodiment, clusters of support pillar structures 20 vertically extend through the alternating stack (32, 46). Each of the support pillar structures 20 comprises a dielectric fill material; and each cluster of support pillar structures 20 within the clusters of support pillar structures 20 laterally surrounds a respective layer contact assembly within the array of layer contact assemblies (81, 84) and within a respective one of the memory-opening-free areas MOFA.

Referring to FIG. 14D, a top-down view of the first alternative configuration of the exemplary structure is illustrated after the processing steps of FIGS. 14A-14C. In the first alternative configuration, the array of layer contact via structures 84 comprises at least one column of layer contact via structures 84 that are arranged along the second horizontal direction hd2 and laterally spaced among one another by subarrays of memory opening fill structures 58, each of the subarrays including a respective subset of the array of memory opening fill structures 58. The array of layer contact assemblies (81, 84) comprises multiple columns of layer contact assemblies (81, 84). Each row of layer contact assemblies (81, 84) within the multiple rows of layer contact assemblies (81, 84) comprises a respective plurality of layer contact assemblies (81, 84) that are arranged along the second horizontal direction hd2. The multiple rows of layer contact assemblies (81, 84) are laterally spaced apart from each other along the first horizontal direction hd1.

In one embodiment, the alternating stack (32, 46) comprises a pair of lengthwise sidewalls that laterally extend along a first horizontal direction hd1 and vertically extend from a bottommost layer of the alternating stack (32, 46) to a topmost layer of the alternating stack (32, 46). The array of memory-opening-free areas MOFA comprises a row of memory-opening-free areas MOFA each laterally extending from one of the pair of lengthwise sidewalls to another of the pair of lengthwise sidewalls.

Referring to FIG. 14E, a top-down view of the second alternative configuration of the exemplary structure is illustrated after the processing steps of FIGS. 14A-14C. In the second alternative configuration, the alternating stack (32, 46) in each memory block comprises a pair of lengthwise sidewalls that laterally extend along a first horizontal direction hd1 and vertically extend from a bottommost layer of the alternating stack (32, 46) to a topmost layer of the alternating stack (32, 46). The array of memory-opening-free areas MOFA is laterally spaced from a lengthwise sidewall of the pair of lengthwise sidewalls by at least one row of memory opening fill structures 58 that is a subset of the array of memory opening fill structures 58 and laterally extends along the first horizontal direction hd1.

In one embodiment, the array of layer contact assemblies (81, 84) comprises a row of layer contact assemblies (81, 84) that are arranged along first horizontal direction hd1. The row of layer contact assemblies (81, 84) is laterally spaced from at least one row of memory opening fill structures 58 within the array of memory opening fill structures 58 by one of the drain-select-level dielectric isolation structures 72.

In one embodiment, clusters of support pillar structures 20 vertically extend through the alternating stack (32, 46). Each of the support pillar structures 20 comprises a dielectric fill material. Each cluster of support pillar structures 20 within the clusters of support pillar structures 20 laterally surrounds a respective layer contact assembly within the array of layer contact assemblies (81, 84) and within a respective one of the memory-opening-free areas MOFA.

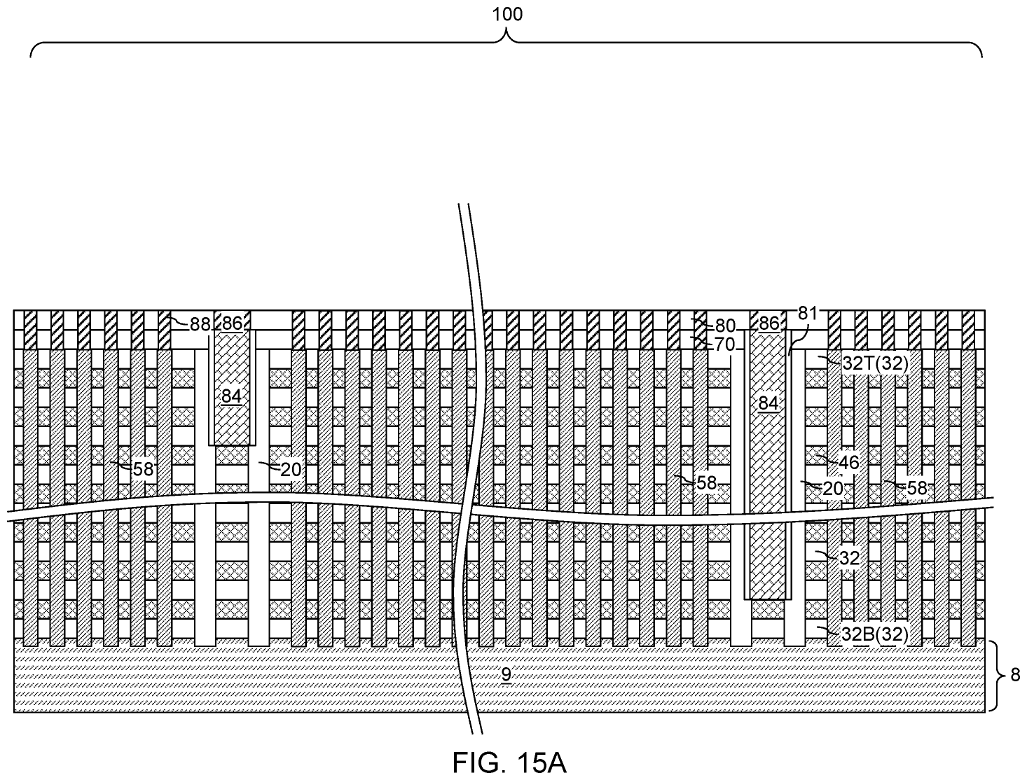

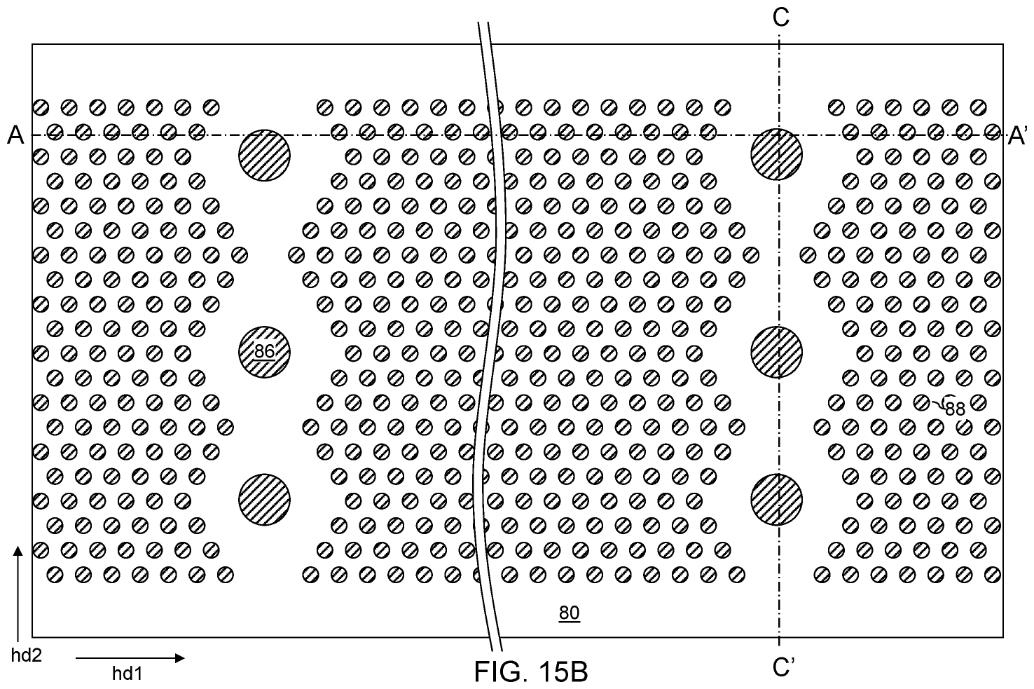

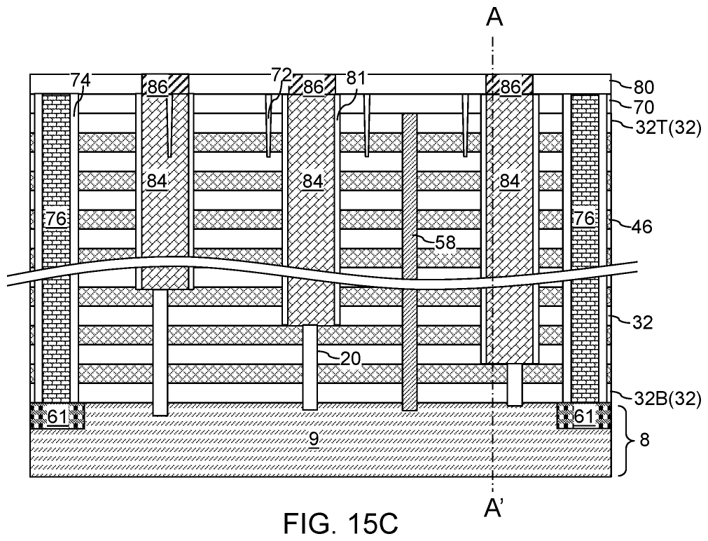

Referring to FIGS. 15A-15C, a contact-level dielectric layer 80 can be formed over the insulating cap layer 70, the alternating stack (32, 46), the array of memory opening fill structures 58, and the layer contact via structures 84, by depositing a dielectric material such as silicon oxide. The thickness of the contact-level dielectric layer 80 may be in a range from 50 nm to 400 nm, although lesser and greater thicknesses may also be employed.

Contact-level via structures (88, 86) can be formed through the contact-level dielectric layer 80. The contact-level via structures (88, 86) may comprise drain contact via structures 88 and contact-level extension via structures 86. Each of the drain contact via structures contacts a respective one of the memory opening fill structures 58, and specifically, a top surface of a respective drain region 63 within the respective one of the memory opening fill structures 58. Each of the contact-level extension via structures contacts a top surface of a respective one of the layer contact via structures 84.

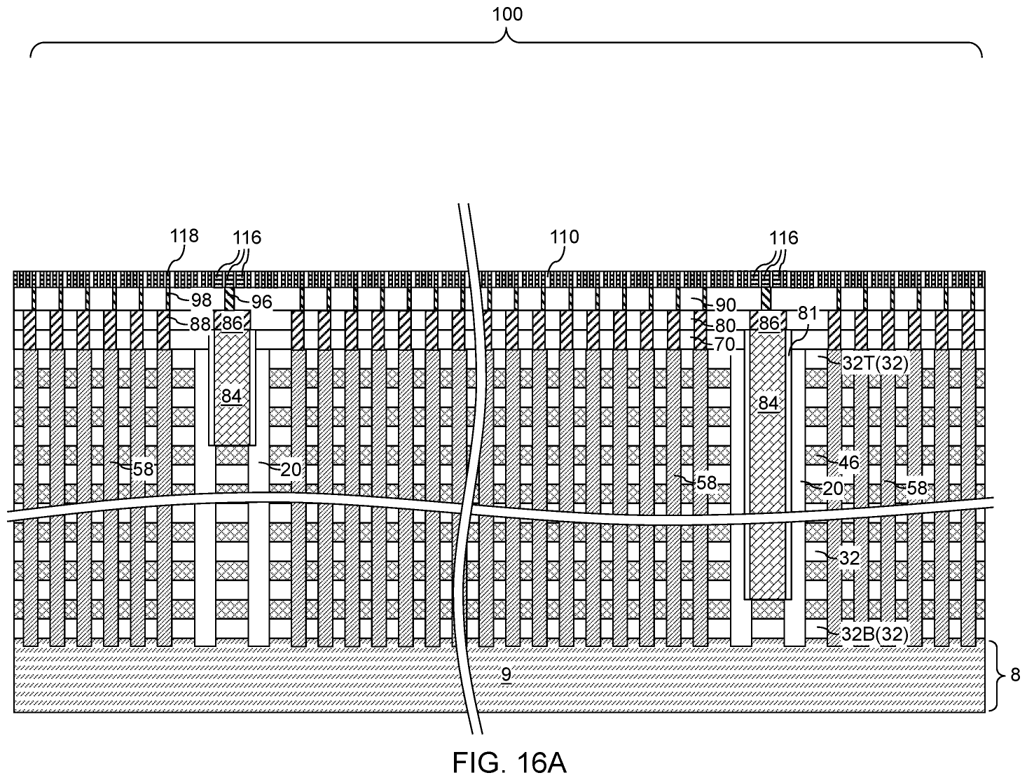

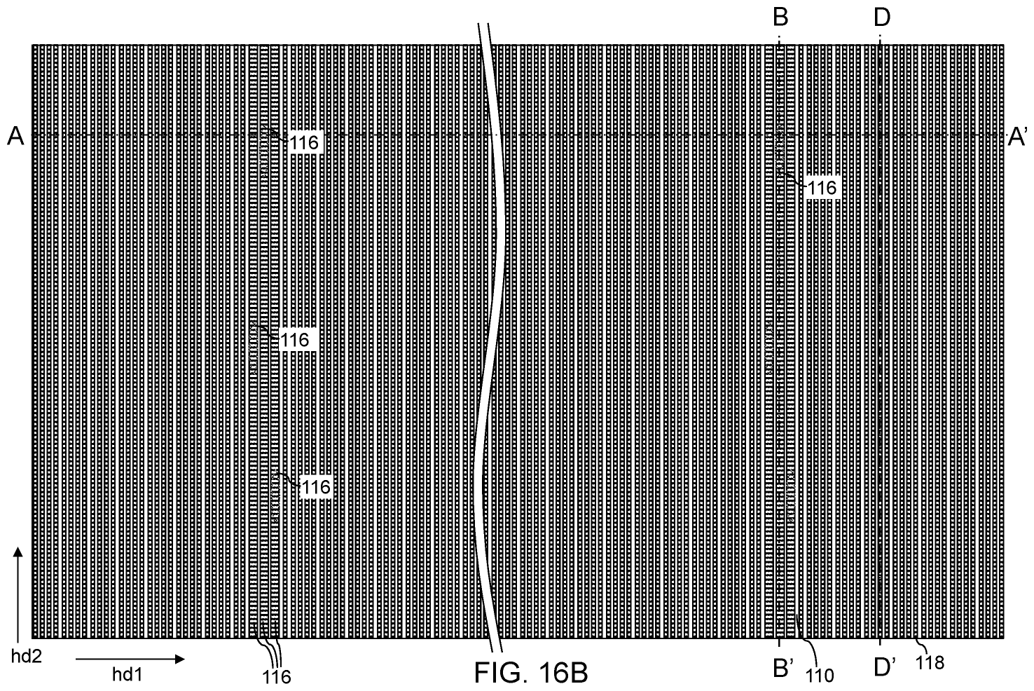

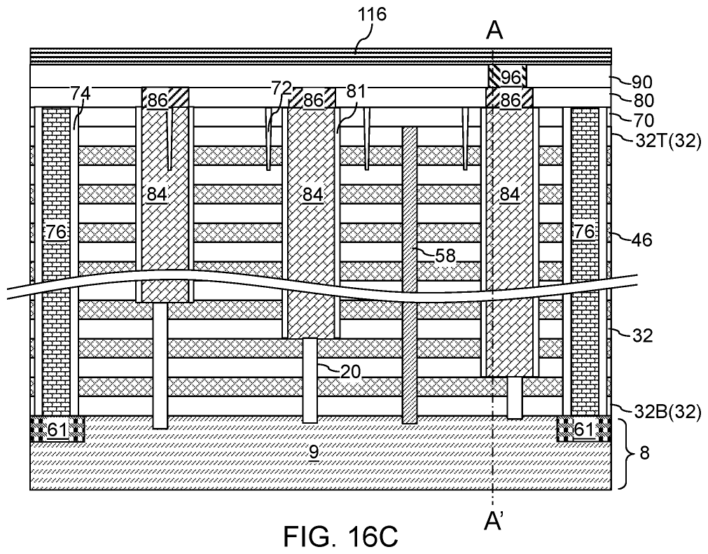

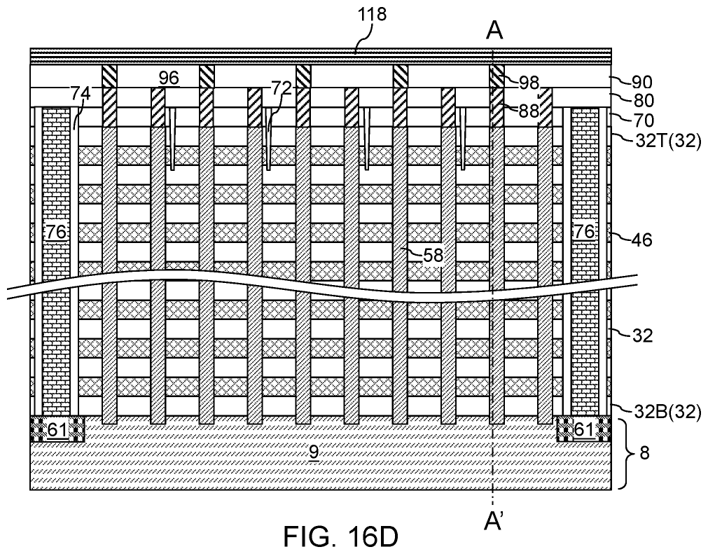

Referring to FIGS. 16A-16D, a connection-level dielectric layer 90 can be formed over the contact-level dielectric layer 80. The connection-level dielectric layer 90 comprises an interconnect-level dielectric (ILD) material, and may have a thickness in a range from 100 nm to 400 nm, although lesser and greater thicknesses may also be employed. Drain-connection via structures 98 and connection-level extension via structures 96 can be formed through the connection-level dielectric layer 90. Each of the drain-connection via structures 98 contacts a respective one of the drain contact via structures 88. Each of the connection-level extension via structures 96 contacts a respective one of the contact-level extension via structures 86.

A line-level dielectric layer 110 can be formed over the connection-level dielectric layer 90. The line-level dielectric layer 110 comprises an interconnect-level dielectric (ILD) material, and may have a thickness in a range from 100 nm to 400 nm, although lesser and greater thicknesses may also be employed. Bit lines 118 and layer-connection metal lines 116 can be formed through the line-level dielectric layer 110. Each bit line 118 laterally extends along the second horizontal direction hd2, and contacts a respective subset of the drain-connection via structures 98 that are arranged along the second horizontal direction hd2. Each layer-connection metal line 116 laterally extends along the second horizontal direction hd2, and may contact a respective connection-level extension via structures 96 in each alternating stack (32, 46). If any memory opening fill structures 58 are located directly under a respective layer-connection metal line 116, then such memory opening fill structures 58 may comprise dummy (i.e., inactive) memory opening fill structures 58 that are not electrically connected to one of the bit lines 118. Such dummy memory opening fill structures 58 may be located in the second alternative configuration of the exemplary structure of FIG. 14E. While three adjacent layer-connection metal lines 116 are shown in FIGS. 16A and 16B, there may be two layer-connection metal lines 116, more than three layer-connection metal lines 116 or no adjacent layer-connection metal lines 116 which are not separated by at least one bit line 118 along the first horizontal direction hd1.

Generally, the bit lines 118 and the layer-connection metal lines 116 can be formed at a same level (such as the level of the line-level dielectric layer 110) over the connection-level dielectric layer 90. The bit lines 118 are laterally spaced apart from each other along the first horizontal direction hd1 and laterally extend along the second horizontal direction hd2. The bit lines 118 contact a respective subset of the drain connection via structures 98, and are electrically connected to a respective subset of the drain regions 63. The layer-connection metal lines 116 are electrically connected to a respective subset of the connection-level extension via structures 96, laterally extend along the second horizontal direction hd2, and are interlaced with the bit lines 118 along the first horizontal direction hd1. The bit lines 118 and the layer-connection metal lines 116 laterally extend over a plurality of alternating stacks (32, 46) along the second horizontal direction hd2. Thus, the bit lines 118 and the layer-connection metal lines 116 have a greater lateral extent along the second horizontal direction hd2 than the maximum lateral extent of any single alternating stack (32, 46) in a respective memory block along the second horizontal direction hd2.

Each of the layer-connection metal lines 116 are electrically connected to a respective one of the layer contact via structures 84, laterally extend along the second horizontal direction hd2, and are interlaced with the bit lines 118 along the first horizontal direction hd1. The layer-connection metal lines 116 have a greater lateral extent along the second horizontal direction hd2 that is greater than a lateral extent of an alternating stack (32, 46) along the second horizontal direction hd2. Thus, the layer-connection metal lines 116 have a greater lateral extent along the second horizontal direction hd2 than a width of a memory block having a lateral distance between the first lateral isolation trench 79 and the second lateral isolation trench 79. Each of the layer-connection metal lines 116 are electrically connected to a respective one of the layer contact via structures 84, laterally extend along the second horizontal direction hd2, and are interlaced with the bit lines 118 along the first horizontal direction hd1.

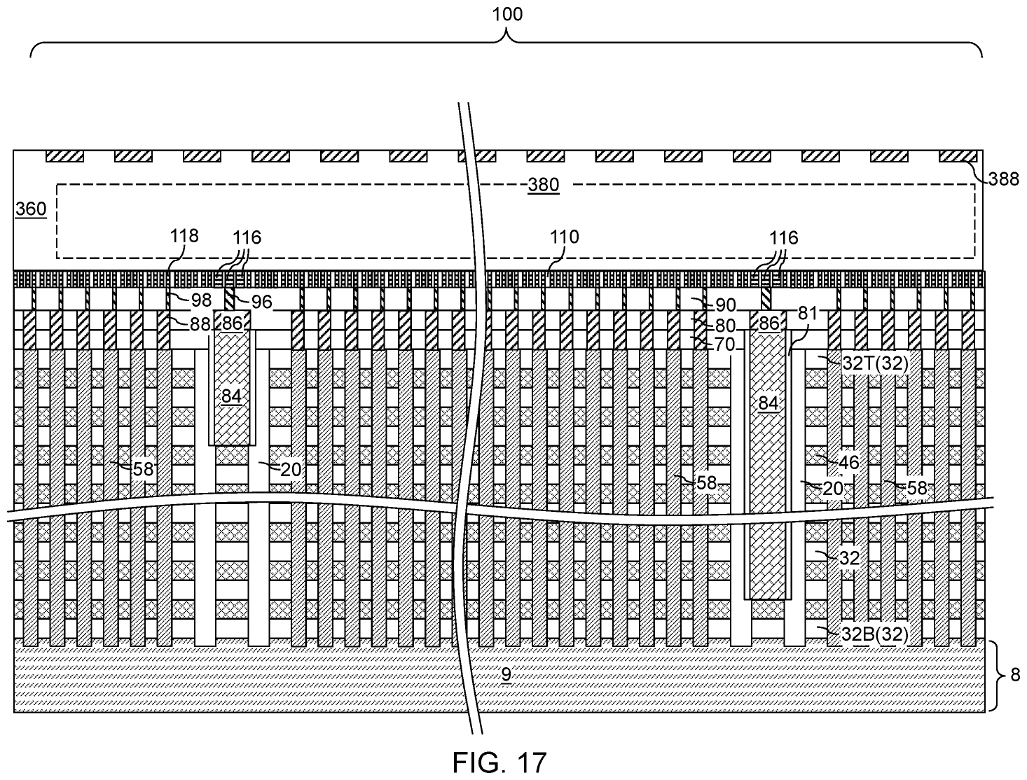

Referring to FIG. 17, upper metal interconnect structures 380 and upper dielectric material layers 360 may be formed above the line-level dielectric layer 110. The upper metal interconnect structures 380 overlie the alternating stack (32, 46), and are embedded within the upper dielectric material layers 360. The upper metal interconnect structures 380 comprise upper metal via structures and upper metal line structures. In one embodiment, the upper metal via structures may have a respective lateral extent that increases with a vertical distance upward from a topmost surface of the alternating stack (32, 46). The upper metal interconnect structures 380 may be electrically connected a respective node of an underlying three-dimensional memory device such as a set of drain regions 63 or an electrically conductive layer 46. Memory-side bonding pads 388 may be formed within the upper dielectric material layers 360. The memory-side bonding pads 388 may be electrically connected to the upper metal interconnect structures 380. Thus, a memory die 900 is provided.

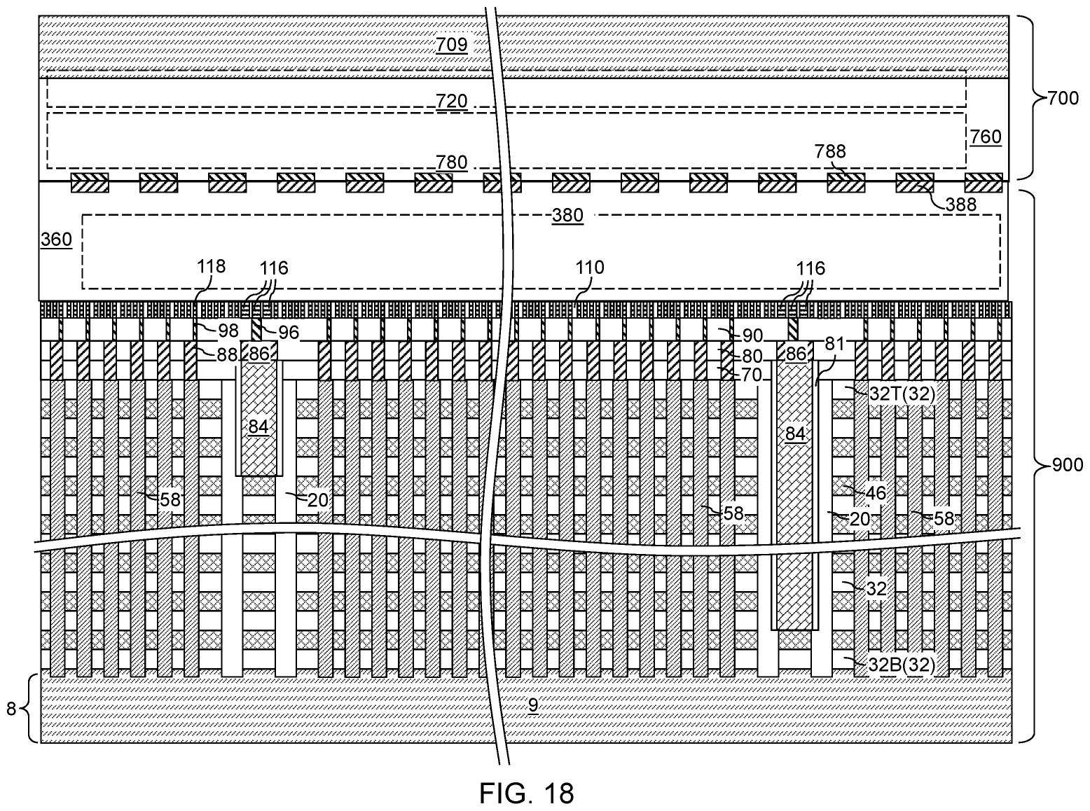

Referring to FIG. 18, a logic die 700 can be provided. The logic die 700 comprises a logic-side substrate 709 (which may be a semiconductor substrate), logic-side semiconductor devices 720 which includes a peripheral circuitry for controlling operation of the three-dimensional memory device within the memory die 900, logic-side metal interconnect structures 780 embedded within logic-side dielectric material layers 760, and logic-side bonding pads 788 configured to mate with the memory-die bonding pads 388. The logic-side metal interconnect structures 780 may comprise logic-side metal lines 784 and logic-side metal via structures 782. The logic-side metal via structures 782 may have a respective variable lateral extent that increases with a vertical distance from a horizontal plane including an interface between the logic-side substrate 709 and the logic-side dielectric material layers 760.

Generally, the logic-side semiconductor devices 720 comprise a control circuitry configured to control operation of the vertical stack of memory elements (e.g., memory cells) within each memory opening fill structure 58 in the memory die 900. The logic-side semiconductor devices 720 may be electrically connected to the logic-side bonding pads 788 through the logic-side metal interconnect structures 780. Thus, the logic-side bonding pads 788 are electrically connected to the logic-side semiconductor devices 720 through the logic-side metal interconnect structures 780.

The logic die 700 can be attached to the memory die 900, for example, by bonding the memory-side bonding pads 388 with the logic-side bonding pads 788. For example, the memory-side bonding pads 388 can be bonded with the logic-side bonding pads 788 by metal-to-metal bonding such as copper-to-copper bonding. In some embodiments, hybrid bonding may be employed, in which contacting surfaces of the upper dielectric material layers 960 and the logic-side dielectric material layers 760 are bonded through dielectric-to-dielectric bonding (such as oxide-to-oxide bonding). The substrate 8 may be either omitted or retained in the bonded assembly of the logic die 700 and the memory die 900.

Generally, various configurations for the upper metal interconnect structures 380 and the memory-die bonding pads 388 may be employed on the side of the memory die 900, and various configurations for the logic-side metal interconnect structures 780 and the logic-side bonding pads 788 may be employed on the side of the logic die 700.

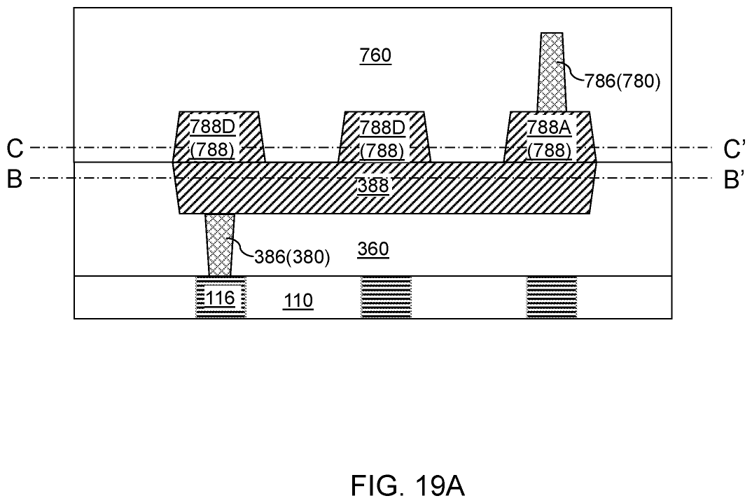

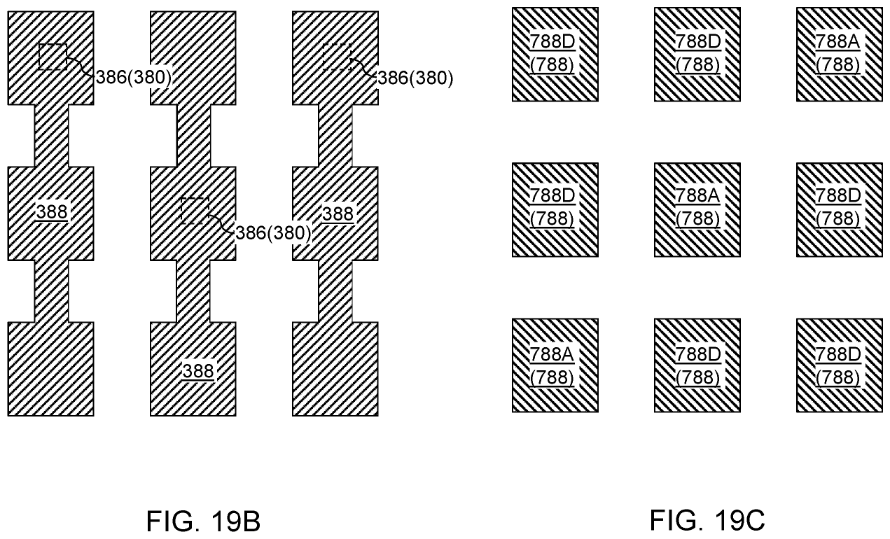

Referring to FIGS. 19A-19C, a first exemplary configuration for the upper metal interconnect structures 380, the memory-die bonding pads 388, the logic-side metal interconnect structures 780, and the logic-side bonding pads 788 is illustrated. In the first exemplary configuration of FIGS. 19A-19C, the upper-level interconnect structures may comprise memory-side pad-level via structures 386 providing direct contact between a respective one of the layer-connection metal lines 116 and a respective one of the memory-side bonding pads 388. In this case, a single metal line level may be employed between the three-dimensional memory array and the memory-side bonding pads 388 in the memory die 900.

In some embodiments, the memory-side bonding pads 388 may be elongated along at least one horizontal direction to bond with a plurality of logic-side bonding pads 788. In some embodiments, a subset of the plurality of logic-side bonding pads 788 may be dummy bonding pads 788D that are not electrically connected to any device of the peripheral circuit 720 in the logic die 700, but are employed to provide uniform bonding between the memory-side bonding pads 388 and the active logic-side bonding pads 788A electrically connected to the peripheral circuit 720 in a bonded structure. In this case, at least one logic-side bonding pad 788 of the plurality of bonding pads 788 is an active logic-side bonding pads 788A that is electrically connected to a respective semiconductor device in the logic die 700, for example, through a respective logic-side pad-level via structure 786. Alternatively, a plurality of logic-side bonding pads 788 may be elongated and bonded to active and dummy memory-side bonding pads. Thus, either a logic-side bonding pad and/or a memory-side bonding pad may function as a lateral interconnection between respective active regions in the logic die 700 and the memory die 900.

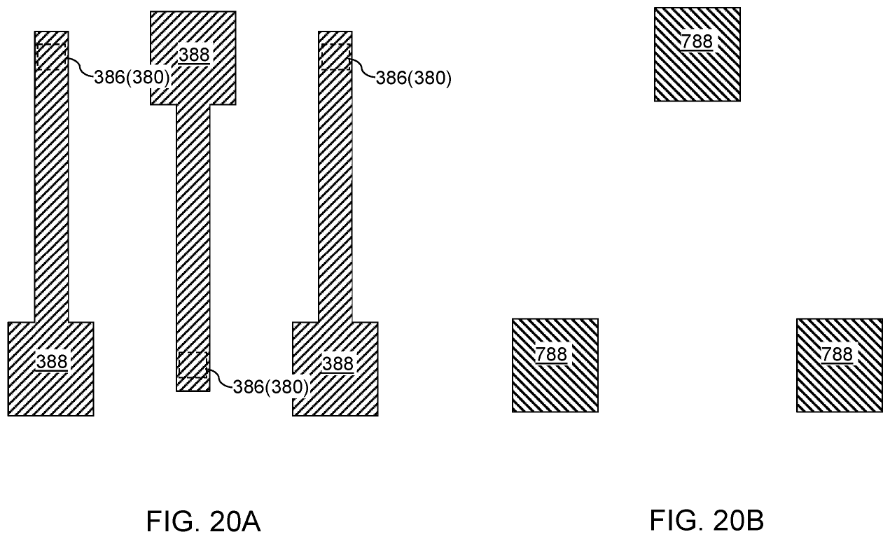

Referring to FIGS. 20A-20B, a second exemplary configuration for the upper metal interconnect structures 380, the memory-die bonding pads 388, the logic-side metal interconnect structures 780, and the logic-side bonding pads 788 is illustrated. In the second exemplary configuration of FIGS. 20A-20B, the memory-side bonding pads 388 and/or the logic-side bonding pads 788 may be formed with a pad-level lateral extension portion such that the respective bonding pad (388, 788) contacts a respective pad-level via structure (386, 786) at a location that is laterally offset from a bonding interface between a memory-side bonding pad 388 and a logic-side bonding pad 788.

Generally speaking, the number of metal interconnect levels in the memory die 900 may be minimized by employing the layer-connection metal lines 116 and by employing suitable modifications to the structures and/or positions of the memory-side bonding pads 388 and logic-side bonding pads 788.

Referring collectively to FIGS. 1-20B and according to various embodiments of the present disclosure, a three-dimensional memory device is comprises: an alternating stack (32, 46) of insulating layers 32 and electrically conductive layers 46; an array of memory openings 49 vertically extending through the alternating stack (32, 46); memory-opening-free areas MOFA located in the array of the memory openings 49 in a plan view; an array of memory opening fill structures 58 located in the array of memory openings 49, wherein each of the memory opening fill structures 58 comprises a respective vertical semiconductor channel 60 and respective of memory elements (e.g., portions of the memory film 50 or floating gates) located at levels of the electrically conductive layers 46; and layer contact assemblies (81, 84) located within the memory-opening-free areas MOFA in the plan view, wherein each of the layer contact assemblies (81, 84) comprises a respective layer contact via structure 84 contacting a respective one of the electrically conductive layers 46 and further comprises a respective insulating spacer 81 that laterally surrounds the respective layer contact via structure 84.

In one embodiment, the layer contact via structures 84 comprise at least one row of layer contact via structures 84 that are arranged along a first horizontal direction hd1 and laterally spaced from each other by subarrays of memory opening fill structures 58, and wherein each of the subarrays includes a respective subset of the array of memory opening fill structures 58.

In one embodiment, each of the memory opening fill structures 58 further comprises a respective drain region 63 contacting a top end of the respective vertical semiconductor channel 60; and the three-dimensional memory device further comprises bit lines 118 laterally spaced apart from each other along a first horizontal direction hd1 and laterally extending along a second horizontal direction hd2. Each of the bit lines 118 is electrically connected to a respective subset of the drain regions 63. In one embodiment, the three-dimensional memory device further comprises layer-connection metal lines 116 located at a same level as the bit lines 118, wherein each of the layer-connection metal lines 116 is electrically connected to a respective one of the layer contact via structures 84, laterally extends along the second horizontal direction hd2, and are interlaced with the bit lines 118 along the first horizontal direction hd1.

In one embodiment, the three-dimensional memory device comprises: a first lateral isolation trench fill structure (74, 76) having a first dielectric sidewall that laterally extends along the first horizontal direction hd1 and contacting each of the insulating layers 32 and the electrically conductive layers 46 within the alternating stack (32, 46); and a second lateral isolation trench fill structure (74, 76) that is laterally spaced from the first lateral isolation trench fill structure (74, 76) along the second horizontal direction hd2 and having a second dielectric sidewall that laterally extends along the first horizontal direction hd1 and contacting each of the insulating layers 32 and the electrically conductive layers 46 within the alternating stack (32, 46). In one embodiment, the layer-connection metal lines 116 have a lateral extent along the second horizontal direction hd2 that is greater than a lateral extent of the alternating stack (32, 46) along the second horizontal direction hd2.

In one embodiment shown in FIG. 14B, the layer contact assemblies (81, 84) comprise multiple rows of layer contact assemblies (81, 84); each row of layer contact assemblies (81, 84) within the multiple rows of layer contact assemblies (81, 84) comprises a respective plurality of layer contact assemblies (81, 84) that are arranged along a first horizontal direction hd1; and the multiple rows of layer contact assemblies (81, 84) are laterally spaced apart from each other along a second horizontal direction hd2.

In one embodiment, the array of memory opening fill structures 58 comprises at least one row of memory opening fill structures 58 that laterally extends along the first horizontal direction hd1 and located between a respective neighboring pair of rows of layer contact assemblies (81, 84) within the multiple rows of layer contact assemblies (81, 84).

In one embodiment shown in FIG. 14D, the alternating stack (32, 46) comprises a pair of lengthwise sidewalls that laterally extend along a first horizontal direction hd1 and vertically extend from a bottommost layer of the alternating stack (32, 46) to a topmost layer of the alternating stack (32, 46); and the memory-opening-free areas MOFA comprise a column of memory-opening-free areas MOFA each laterally extending from one of the pair of lengthwise sidewalls to another of the pair of lengthwise sidewalls.

In one embodiment, the alternating stack (32, 46) comprises a pair of lengthwise sidewalls that laterally extend along a first horizontal direction hd1 and vertically extend from a bottommost layer of the alternating stack (32, 46) to a topmost layer of the alternating stack (32, 46); and the array of memory-opening-free areas MOFA is laterally spaced from a lengthwise sidewall of the pair of lengthwise sidewalls by at least one row of memory opening fill structures 58 that is a subset of the array of memory opening fill structures 58 that laterally extends along the first horizontal direction hd1.

In one embodiment, the three-dimensional memory device comprises drain-select-level dielectric isolation structures 72 laterally extending along a first horizontal direction hd1, and vertically extending through at least one electrically conductive layer 46 including a topmost electrically conductive layer 46 within the alternating stack (32, 46).

In one embodiment shown in FIG. 14E, the layer contact assemblies (81, 84) comprise a row of layer contact assemblies (81, 84) that are arranged along first horizontal direction hd1; and the row of layer contact assemblies (81, 84) is laterally spaced from at least one row of memory opening fill structures 58 within the array of memory opening fill structures 58 by one of the drain-select-level dielectric isolation structures 72.

In one embodiment, the layer contact assemblies (81, 84) comprise a row of layer contact assemblies (81, 84) that are arranged along first horizontal direction hd1; and one of the drain-select-level dielectric isolation structures 72 extends through an upper portion of each layer contact assembly within the row of layer contact assemblies (81, 84).

In one embodiment, the three-dimensional memory device comprises clusters of support pillar structures 20 vertically extending through the alternating stack (32, 46), wherein: each of the support pillar structures 20 comprises a dielectric fill material; and each cluster of support pillar structures 20 within the clusters of support pillar structures 20 laterally surrounds a respective layer contact assembly of the layer contact assemblies (81, 84) located within a respective one of the memory-opening-free areas MOFA.

In one embodiment, the memory die 900 includes at least one elongated memory-side bonding pad 388. The logic die 700 comprises a peripheral circuit 720, at least one active logic-side bonding pad 788A electrically connected to the peripheral circuit 720 and bonded to the elongated memory-side bonding pad 388, and at least one dummy logic-side bonding pad 788D not electrically connected to the peripheral circuit 720 and bonded to the elongated memory-side bonding pad 388.

The various embodiments of the present disclosure can be employed to form layer contact via structures 84 within a memory array region 100 without forming a staircase region having stepped surfaces. Furthermore, the active memory array region 100 area is increased, while chip size and shunt resistance is decreased by forming the layer contact via structures 84 between the memory opening fill structures 58 in the memory array region 100 instead of in a separate contact region located adjacent to the memory array region 100.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
an alternating stack of insulating layers and electrically conductive layers;
an array of memory openings vertically extending through the alternating stack;
memory-opening-free areas located in the array of the memory openings in a plan view;
an array of memory opening fill structures located in the array of memory openings, wherein each of the memory opening fill structures comprises a respective vertical semiconductor channel and respective memory elements located at levels of the electrically conductive layers; and
layer contact assemblies located within the memory-opening-free areas in the plan view, wherein each of the layer contact assemblies comprises a respective layer contact via structure contacting a respective one of the electrically conductive layers and further comprises a respective insulating spacer that laterally surrounds the respective layer contact via structure.

2. The three-dimensional memory device of claim 1, wherein the layer contact via structures comprise at least one row of layer contact via structures that are arranged along a first horizontal direction and laterally spaced from each other by subarrays of memory opening fill structures, and wherein each of the subarrays includes a respective subset of the array of memory opening fill structures.

3. The three-dimensional memory device of claim 1, wherein:
each of the memory opening fill structures further comprises a respective drain region contacting a top end of the respective vertical semiconductor channel;
the three-dimensional memory device further comprises bit lines laterally spaced apart from each other along a first horizontal direction and laterally extending along a second horizontal direction;
each of the bit lines is electrically connected to a respective subset of the drain regions.

4. The three-dimensional memory device of claim 3, further comprising layer-connection metal lines located at a same level as the bit lines, wherein each of the layer-connection metal lines is electrically connected to a respective one of the layer contact via structures, laterally extends along the second horizontal direction, and is interlaced with the bit lines along the first horizontal direction.

5. The three-dimensional memory device of claim 4, further comprising:
a first lateral isolation trench fill structure having a first dielectric sidewall that laterally extends along the first horizontal direction and contacting each of the insulating layers and the electrically conductive layers within the alternating stack; and
a second lateral isolation trench fill structure that is laterally spaced from the first lateral isolation trench fill structure along the second horizontal direction and having a second dielectric sidewall that laterally extends along the first horizontal direction and contacting each of the insulating layers and the electrically conductive layers within the alternating stack.

6. The three-dimensional memory device of claim 3, wherein the layer-connection metal lines have a lateral extent along the second horizontal direction that is greater than a lateral extent of the alternating stack along the second horizontal direction.

7. The three-dimensional memory device of claim 1, further comprising:
at least one elongated memory-side bonding pad; and
a logic die comprising:
a peripheral circuit;
at least one active logic-side bonding pad electrically connected to the peripheral circuit and bonded to the elongated memory-side bonding pad; and
at least one dummy logic-side bonding pad not electrically connected to the peripheral circuit and bonded to the elongated memory-side bonding pad.

8. The three-dimensional memory device of claim 1, wherein:
the contact assemblies comprise multiple rows of layer contact assemblies;
each row of layer contact assemblies within the multiple rows of layer contact assemblies comprises a respective plurality of layer contact assemblies that are arranged along a first horizontal direction;
the multiple rows of layer contact assemblies are laterally spaced apart from each other along a second horizontal direction; and
the array of memory opening fill structures comprises at least one row of memory opening fill structures that laterally extends along the first horizontal direction and located between a respective neighboring pair of rows of layer contact assemblies within the multiple rows of layer contact assemblies.

9. The three-dimensional memory device of claim 1, wherein:
the alternating stack comprises a pair of lengthwise sidewalls that laterally extend along a first horizontal direction and vertically extend from a bottommost layer of the alternating stack to a topmost layer of the alternating stack; and
the memory-opening-free areas comprise a column of memory-opening-free areas laterally extending from one of the pair of lengthwise sidewalls to another of the pair of lengthwise sidewalls.

10. The three-dimensional memory device of claim 1, wherein:
the alternating stack comprises a pair of lengthwise sidewalls that laterally extend along a first horizontal direction and vertically extend from a bottommost layer of the alternating stack to a topmost layer of the alternating stack; and
the array of memory-opening-free areas is laterally spaced from a lengthwise sidewall of the pair of lengthwise sidewalls by at least one row of memory opening fill structures that is a subset of the array of memory opening fill structures that laterally extends along the first horizontal direction.

11. The three-dimensional memory device of claim 1, further comprising drain-select-level dielectric isolation structures laterally extending along a first horizontal direction, and vertically extending through at least one electrically conductive layer including a topmost electrically conductive layer within the alternating stack.

12. The three-dimensional memory device of claim 11, wherein:
the layer contact assemblies comprise a row of layer contact assemblies that are arranged along first horizontal direction; and
the row of layer contact assemblies is laterally spaced from at least one row of memory opening fill structures within the array of memory opening fill structures by one of the drain-select-level dielectric isolation structures.

13. The three-dimensional memory device of claim 11, wherein:
the layer contact assemblies comprise a row of layer contact assemblies that are arranged along first horizontal direction; and
one of the drain-select-level dielectric isolation structures extends through an upper portion of each layer contact assembly within the row of layer contact assemblies.

14. The three-dimensional memory device of claim 1, further comprising clusters of support pillar structures vertically extending through the alternating stack, wherein:
each of the support pillar structures comprises a dielectric fill material; and
each cluster of support pillar structures within the clusters of support pillar structures laterally surrounds a respective layer contact assembly of the layer contact assemblies located within a respective one of the memory-opening-free areas.

15. A method of forming a three-dimensional memory device, comprising:
forming an alternating stack of insulating layers and sacrificial material layers over a substrate;
forming an array of memory openings through the alternating stack, wherein the array of memory openings is arranged to provide memory-opening-free areas therein in a plan view;
forming an array of memory opening fill structures in the array of memory openings, wherein each of the memory opening fill structures comprises a respective vertical semiconductor channel and respective memory elements located at levels of the electrically conductive layers;
forming in-process via structures including sacrificial via fill material portions within areas of the memory-opening-free areas in the plan view, wherein each of the in-process via structures vertically extends through a respective subset of layers within the alternating stack;
replacing the sacrificial material layers with electrically conductive layers; and
replacing the sacrificial via fill material portions with layer contact via structures to form layer contact assemblies, wherein each of the layer contact assemblies comprises a respective layer contact via structure contacting a respective one of the electrically conductive layers and further comprises a respective insulating spacer that laterally surrounds the respective layer contact via structure.

16. The method of claim 15, wherein:
each of the memory opening fill structures further comprises a respective drain region contacting a top end of the respective vertical semiconductor channel;
the method further comprises forming bit lines and layer-connection metal lines at a same level over the memory opening fill structures and the layer contact assemblies;
the bit lines are laterally spaced apart from each other along a first horizontal direction, laterally extend along a second horizontal direction, and are electrically connected to a respective subset of the drain regions; and
each of the layer-connection metal lines are electrically connected to a respective one of the layer contact via structures, laterally extend along the second horizontal direction, and are interlaced with the bit lines along the first horizontal direction.

17. The method of claim 16, further comprising forming a first lateral isolation trench and a second lateral isolation trench that laterally extend along a first horizontal direction and laterally spaced apart along a second horizontal direction through the alternating stack, wherein:
the sacrificial material layers are removed by providing an etchant into the first lateral isolation trench and the second lateral isolation trench, and the electrically conductive layers are formed by providing a precursor gas for a conductive material of the electrically conductive layers into the first lateral isolation trench and the second lateral isolation trench; and
the layer-connection metal lines have a greater lateral extent along the second horizontal direction than a lateral distance between the first lateral isolation trench and the second lateral isolation trench.

18. The method of claim 15, further comprising:
forming via cavities having different depths within the memory-opening-free areas in the plan view;
depositing an insulating liner layer and a sacrificial via fill material in the via cavities; and
removing portions of the sacrificial via fill material from above a horizontal plane including a topmost surface of the insulating liner layer, wherein remaining portions of the sacrificial via fill material comprise the sacrificial via fill material portions.

19. The method of claim 15, further comprising:
forming a contact-level dielectric layer over the alternating stack, the array of memory opening fill structures, and the layer contact via structures;
forming drain contact via structures and contact-level extension via structures through the contact-level dielectric layer, wherein each of the drain contact via structures contacts a respective one of the memory opening fill structures and each of the contact-level extension via structures contacts a respective one of the layer contact via structures;
forming a connection-level dielectric layer over the contact-level dielectric layer; and
forming drain connection via structures and connection-level extension via structures through the connection-level dielectric layer, wherein each of the drain connection via structures contacts a respective one of the drain contact via structures and each of the connection-level extension via structures contacts a respective one of the contact-level extension via structures.

20. The method of claim 19, further comprising forming bit lines and layer-connection metal lines at a same level over the connection-level dielectric layer, wherein:
the bit lines contact a respective subset of the drain connection via structures; and
the layer-connection metal lines have a greater lateral extent along the second horizontal direction than a maximum lateral extent of the alternating stack along the second horizontal direction.
